(19) United States
(12) Patent Application Publication
(10) Pub. No.: US 2025/0079195 A1
(43) Pub. Date: Mar. 6, 2025

(54) SUBSTRATE PROCESSING APPARATUS, SUBSTRATE PROCESSING METHOD AND NON-TRANSITORY COMPUTER READABLE RECORDING MEDIUM STORING SUBSTRATE PROCESSING PROGRAM

(71) Applicant: SCREEN Holdings Co., Ltd., Kyoto (JP)

(72) Inventors: Tomomi HIGUCHI, Kyoto-shi (JP); Masaki INABA, Kyoto-shi (JP); Linh Da HO, Kyoto-shi (JP); Yutaka IWAKAWA, Kyoto-shi (JP); Naoki FUJIWARA, Kyoto-shi (JP); Naohiko YOSHIHARA, Kyoto-shi (JP)

(21) Appl. No.: 18/820,936

(22) Filed: Aug. 30, 2024

(30) Foreign Application Priority Data
Aug. 30, 2023 (JP) 2023-140400
Dec. 28, 2023 (JP) 2023-223630

(51) Int. Cl. H01L 21/67; G03F 7/42

(52) U.S. Cl. CPC H01L 21/67017; G03F 7/422

(57) ABSTRACT

A substrate processing apparatus that generates a third processing liquid using a first processing liquid and a second processing liquid, include a first supply path connected to a discharge port, a plurality of second supply paths respectively connected to the first supply path at a plurality of mixing positions having different flow-path lengths to the discharge port, a first supplier that supplies the first processing liquid to the first supply path, and a second supplier that supplies the second processing liquid to the first supply path through the plurality of second supply paths, wherein at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

### BACKGROUND

### Technical Field

The present disclosure relates to a substrate processing apparatus, a substrate processing method executed by the substrate processing apparatus, and a non-transitory computer readable recording medium storing a substrate processing program.

### Description of Related Art

In a lithography process in manufacturing a semiconductor device or the like, a resist film is formed on an entire surface to be processed of a substrate. As a method of removing the resist film, there is an SPM process. In the SPM process, a Sulfuric Acid Hydrogen Peroxide Mixture (SPM) liquid is generated using a sulfuric acid (H₂SO₄) and a hydrogen peroxide solution (H₂O₂). The SPM liquid is supplied to the substrate, so that the resist film formed on the substrate is removed. The chemical reaction in which the SPM liquid is generated using a sulfuric acid and a hydrogen peroxide solution is an exothermic reaction. Generally, in order to sufficiently utilize the resist stripping ability of the SPM liquid, it is necessary that the temperature of the SPM supplied to the substrate is equal to or higher than 160° C. A technique for adjusting the temperature of the SPM liquid is described in JP 2008-4819 A.

JP 2008-4819 A describes a substrate processing apparatus for supplying a sulfuric acid hydrogen peroxide solution to an obverse surface of a substrate to strip and remove a resist from the obverse surface of the substrate, that is characterized by including a mixer for mixing a sulfuric acid with a hydrogen peroxide solution and generating a sulfuric acid hydrogen peroxide solution, a discharger for discharging a sulfuric acid hydrogen peroxide solution generated by the mixer and supplying the sulfuric acid hydrogen peroxide solution to the obverse surface of the substrate, a path-length changing means that changes a length of a supply path for the sulfuric acid hydrogen peroxide solution from the mixer to the discharger, a liquid-temperature detecting means for detecting a temperature of the sulfuric acid hydrogen peroxide solution supplied from the mixer to the discharger, and a controlling means for controlling the path-length changing means based on a liquid temperature detected by the liquid-temperature detecting means such that the sulfuric acid hydrogen peroxide solution having a temperature equal to or higher than a predetermined reference temperature is supplied to the discharger.

### SUMMARY

The progress of a first chemical reaction in a case in which a SPM liquid is generated using a sulfuric acid and a hydrogen peroxide solution is promoted at a temperature equal to or higher than a first temperature. On the other hand, with a temperature being equal to or higher than a second temperature lower than the first temperature, the progress of a second chemical reaction in which a hydrogen peroxide solution is broken down into water and oxygen is promoted. Thus, in regard to each mixing of a sulfuric acid and a hydrogen peroxide solution, the first chemical reaction and a second chemical reaction progress at the same time. Therefore, it is necessary to use a sufficient amount of a hydrogen peroxide solution to cause the first chemical reaction which the hydrogen peroxide solution undergoes with a sulfuric acid while the hydrogen peroxide solution undergoes the second chemical reaction. On the other hand, from the viewpoint of environmental protection, it is desired to reduce the consumption of a chemical liquid used for generating the SPM liquid.

An object of the present disclosure is to provide a substrate processing apparatus capable of reducing consumption of a chemical liquid to be used.

A substrate processing apparatus according to one aspect of the present disclosure that generates a third processing liquid using a first processing liquid and a second processing liquid and processes a substrate using the third processing liquid, includes a discharge port, a first supply path connected to the discharge port, a plurality of second supply paths respectively connected to the first supply path at a plurality of mixing positions having different flow-path lengths to the discharge port, a first supplier that supplies the first processing liquid to the first supply path, and a second supplier that supplies the second processing liquid to the first supply path through the plurality of second supply paths, wherein at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

A substrate processing method according to another aspect of the present disclosure of generating a third processing liquid using a first processing liquid and a second processing liquid, wherein the substrate processing method is executed by a substrate processing apparatus that processes a substrate using the third processing liquid, the substrate processing apparatus includes a discharge port, a first supply path connected to the discharge port, a plurality of second supply paths respectively connected to the first supply path at a plurality of mixing positions having different flow-path lengths to the discharge port, and the substrate processing method includes supplying the first processing liquid to the first supply path, and supplying the second processing liquid to the first supply path through the plurality of second supply paths, and at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

A non-transitory computer readable recording medium storing a substrate processing program according to another aspect of the present disclosure executed by a computer that controls a substrate processing apparatus, with the substrate processing apparatus generating a third processing liquid using a first processing liquid and a second processing liquid and processing a substrate using the third processing liquid, wherein the substrate processing apparatus includes a discharge port for discharging the third processing liquid, a first supply path connected to the discharge port, and a plurality of second supply paths respectively connected to the first supply path at a plurality of mixing positions having different flow-path lengths to the discharge port, the substrate processing program causes the computer to execute a step of supplying the first processing liquid to the first supply path, and a step of supplying the second processing liquid to the first supply path through the plurality of second supply paths, and at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

With the present disclosure, it is possible to reduce the consumption of a chemical liquid to be used.

Other features, elements, characteristics, and advantages of the present disclosure will become more apparent from the following description of preferred embodiments of the present disclosure with reference to the attached drawings.

### BRIEF DESCRIPTION OF THE DRAWING

FIG. 1 is a diagram showing one example of the configuration of a substrate processing apparatus;

FIG. 2 is a plan view of the substrate processing apparatus;

FIG. 3 is a schematic diagram for explaining the configuration of a nozzle arm;

FIG. 4 is an enlarged schematic view of a discharge nozzle;

FIG. 5 is a cross-sectional view of FIG. 4 taken along the line A-A;

FIG. 6 is a diagram showing one example of the configuration of a controller;

FIG. 7 is a block diagram showing one example of the functional configuration of the controller;

FIG. 8 is a flowchart for explaining one example of a flow of a substrate process;

FIG. 9 is a schematic diagram for explaining a nozzle arm of a substrate processor used in a first comparative example;

FIG. 10 is a first diagram showing the result of a first experiment;

FIG. 11 is a second diagram showing the result of a second experiment;

FIG. 12 is a schematic diagram for explaining a nozzle arm of a substrate processor used in a second comparative example;

FIG. 13 is a diagram showing the result of a second experiment;

FIG. 14 is a first schematic diagram for explaining a nozzle arm of a substrate processor of a second modified example;

FIG. 15 is a second schematic diagram for explaining a nozzle arm of a substrate processor of a third modified example;

FIG. 16 is a block diagram showing one example of the functional configuration of a controller in a second embodiment;

FIG. 17 is a diagram showing one example of the format of an allocation table;

FIG. 18 is a flowchart for explaining one example of a flow of a substrate process in the second embodiment;

FIG. 19 is a block diagram showing one example of the functional configuration of a controller in a third embodiment;

FIG. 20 is a diagram showing one example of the format of history information;

FIG. 21 is a flowchart for explaining one example of a flow of a substrate process in the third embodiment;

FIG. 22 is a block diagram showing one example of the functional configuration of a controller in a fourth embodiment;

FIG. 23 is a diagram showing one example of the format of history information in the fourth embodiment; and

FIG. 24 is a flowchart showing one example of a flow of an allocation table generation process.

### DETAILED DESCRIPTION

A substrate processing apparatus and a substrate processing method according to one embodiment of the present disclosure will be described below with reference to the drawings. In the following description, a substrate refers to a substrate for an FPD (Flat Panel Display) that is used for a liquid crystal display device, an organic EL (Electro Luminescence) display device or the like, a semiconductor substrate, a substrate for an optical disc, a substrate for a magnetic disc, a substrate for a magneto-optical disc, a substrate for a photomask, a ceramic substrate, a substrate for a solar cell or the like.

### First Embodiment

### (1) Overall Configuration of Substrate Processing Apparatus

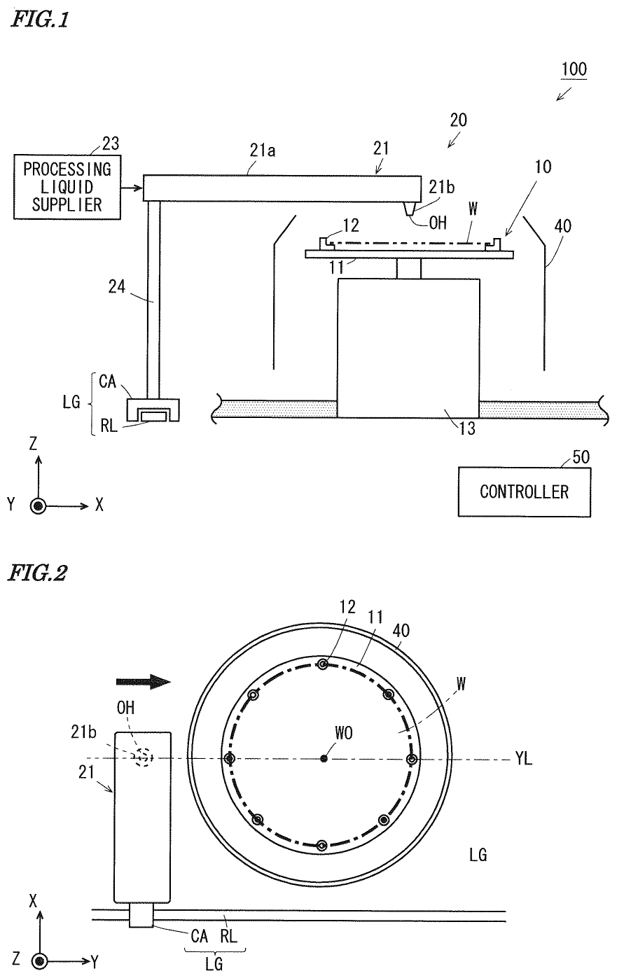

FIG. 1 is a side view showing one example of the configuration of a substrate processing apparatus. FIG. 2 is a plan view of the substrate processing apparatus. In each of FIGS. 1 and 2, X, Y and Z directions orthogonal to one another are defined for the clarity of a positional relationship. The X and Y directions are orthogonal to each other within a horizontal plane, and the Z direction corresponds to an upward-and-downward direction (vertical direction). As shown in FIGS. 1 and 2, the substrate processing apparatus 100 includes a spin chuck (rotation holder) 10, a nozzle unit 20, a splash guard 40 and a controller 50. The controller 50 controls the operations of the spin chuck 10, the nozzle unit 20 and the splash guard 40.

The spin chuck 10, the nozzle unit 20 and the splash guard 40 are accommodated in a processing chamber. The processing chamber has four side-surface portions, a ceiling portion and a bottom portion. In one side-surface portion of the processing chamber, a transfer opening (not shown) for transferring a substrate between the inside of the processing chamber and the outside of the processing chamber is formed. Further, a filter fan unit (FFU) is provided in the ceiling portion of the processing chamber. In the processing chamber, the FFU generates a downward flow of clean air.

The spin chuck 10 includes a spin base 11, a plurality of chuck pins 12 and a spin motor 13. The spin base 11 is attached to the upper end of a rotation shaft of the spin motor 13. A rotational force of the spin motor 13 is transmitted to the spin base 11, and the spin base 11 holding the substrate W is rotated. In the present embodiment, the rotation shaft of the spin motor 13 is set to extend in the vertical direction. The spin base 11 has a holding surface orthogonal to the rotation shaft of the spin motor 13. The plurality of chuck pins 12 are arranged on the holding surface of the spin base 11. The plurality of chuck pins 12 are arranged at equal intervals on a concentric circle centered at the rotation shaft of the spin base 11. At least one of the plurality of chuck pins 12 is fixed to the spin base 11 so as to be rotatable about the rotation shaft orthogonal to the holding surface, and can change its state between the state of holding the outer peripheral end of the substrate W and the state of not holding the outer peripheral end of the substrate W. During a substrate process, the substrate W is held on the spin base 11 in a horizontal attitude with the plurality of chuck pins 12 holding the substrate W.

The splash guard 40 surrounds the spin chuck 10 in plan view. In side view, the splash guard 40 is movable in the vertical direction by a moving mechanism (not shown). During the substrate process, the splash guard 40 is lifted to a position where the upper end of the splash guard 40 is above the substrate W held by the spin chuck 10. In this case, the splash guard 40 receives droplets splashed from the rotating substrate W held by the spin base 11. The droplets received by the splash guard 40 are collected by a collector (not shown). When the substrate W is carried in before a substrate processing operation and when the substrate W is carried out after the substrate processing operation, the splash guard 40 is lowered to a position where the upper end of the splash guard 40 is lower than the spin base 11 of the spin chuck 10. This enables the substrate W on the spin chuck 10 to be carried in and out.

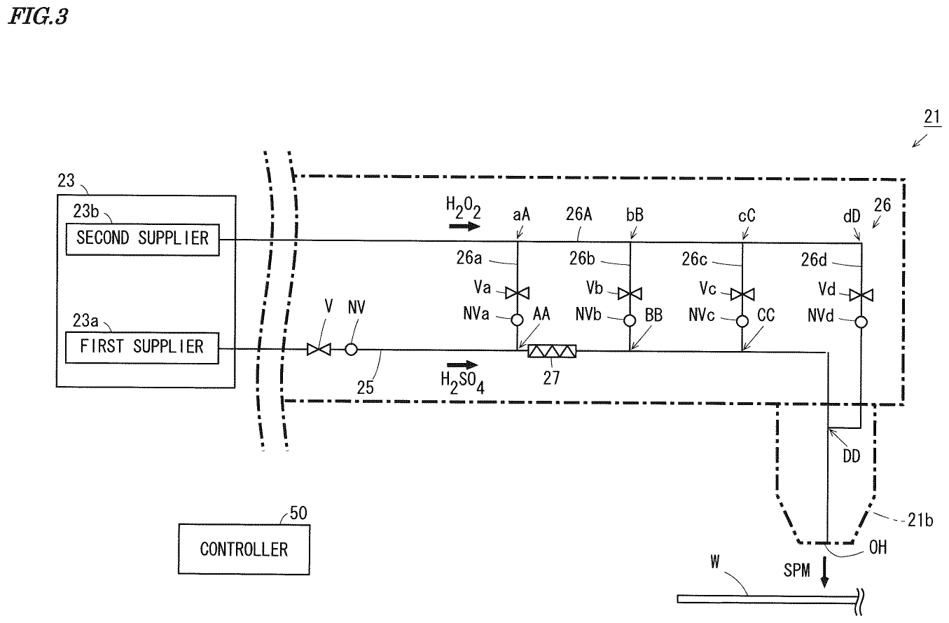

The nozzle unit 20 includes a nozzle arm 21, a holding arm 24, a linear guide LG and a processing liquid supplier 23. The nozzle arm 21 includes a discharge arm 21a and a discharge nozzle 21b. The discharge arm 21a has a rectangular parallelepiped shape elongated in the X direction. The discharge nozzle 21b is provided at one end in the longitudinal direction of the lower surface of the discharge arm 21a, and the other end in the longitudinal direction of the lower surface of the discharge arm 21a is fixed to the holding arm 24. The discharge nozzle 21b has a discharge port OH. The discharge port OH is an opening that opens downwardly. The discharge arm 21a accommodates a plurality of pipes therein. As shown in FIG. 3, the plurality of pipes include a first supply pipe 25 and a second supply pipe 26. The processing liquid supplier 23 includes a first supplier 23a and a second supplier 23b. One end of the first supply pipe 25 and one end of the second supply pipe 26 are respectively connected to the first supplier 23a and the second supplier 23b. The other end of the first supply pipe 25 is connected to the discharge nozzle 21b, and the other end of the second supply pipe 26 is connected to the first supply pipe 25.

The linear guide LG includes a carriage CA, a rail RL and a pulse motor. The rail RL of the linear guide LG is arranged outside of the splash guard 40 in plan view and has a bar shape extending in the Y direction. The carriage CA is slidably connected to the rail RL. The pulse motor moves the carriage CA along the rail RL.

The holding arm 24 is a bar-shaped member extending in the upward-and-downward direction. The upper end of the holding arm 24 is fixed to the discharge arm 21a. The lower end of the holding arm 24 is fixed to the carriage CA. The length in the longitudinal direction of the holding arm 24 is set such that the discharge port OH of the discharge nozzle 21b is located at a position higher than the substrate W held by the spin chuck 10 by a predetermined distance. Thus, the discharge port OH of the discharge nozzle 21b is held by the discharge arm 21a and the holding arm 24 at the position higher than the substrate W held by the spin chuck 10 by the predetermined distance.

When the carriage CA is moved along the rail RL, the discharge arm 21a held by the holding arm 24 is moved in parallel to the Y direction. The length in the longitudinal direction of the discharge arm 21a is set such that the discharge port OH of the discharge nozzle 21b travels on a movement line YL passing through the center WO of the substrate W and being parallel to the Y direction. Thus, when the carriage CA moves along the linear guide LG, the discharge port OH of the discharge nozzle 21b is moved on the movement line YL while being higher than the substrate W held by the spin chuck 10 by the predetermined distance.

When the discharge arm 21a is moved, a processing liquid supplied from the processing liquid supplier 23 is discharged from the discharge port OH of the discharge nozzle 21b. Thus, the processing liquid is supplied from the discharge port OH of the discharge nozzle 21b of the nozzle arm 21 to the upper surface of the substrate W held on the spin base 11 by the spin chuck 10. Hereinafter, this operation is referred to as a scanning operation of the discharge nozzle 21b. The processing liquid supplied to the upper surface of the substrate W in the present embodiment is a sulfuric acid hydrogen peroxide mixture (SPM) liquid. The SPM liquid is generated in the nozzle arm 21.

### (2) Configuration of Nozzle Arm 21

FIG. 3 is a schematic diagram for explaining the configuration of the nozzle arm 21. The nozzle arm 21 accommodates the first supply pipe 25 and the second supply pipe 26. The first supply pipe 25 has both ends. One end of the first supply pipe 25 is connected to the first supplier 23a for supplying a first processing liquid, and the other end of the first supply pipe 25 is connected to the discharge nozzle 21b. The flow path extending from the one end of the first supply pipe 25 connected to the first supplier 23a to the discharge port OH of the discharge nozzle 21b is an example of a first supply path.

The second supply pipe 26 includes a main pipe 26A and a plurality of branch pipes 26a to 26d. The main pipe 26A has both ends. One end of the main pipe 26A is connected to the second supplier 23b, and the other end of the main pipe 26A is connected to the branch pipe 26d. The one end of each of the plurality of branch pipes 26a to 26d is connected to the main pipe 26A at each of a plurality of different branch points aA to dD of the main pipe 26A, and the other end of each of the plurality of branch pipes 26a to 26d is connected to the first supply pipe 25 at each of a plurality of first mixing positions AA to fourth mixing positions DD of the first supply pipe 25.

One end of the branch pipe 26a is connected to the main pipe 26A at the branch point aA, and the other end of the branch pipe 26a is connected to the first supply pipe 25 at the first mixing position AA. In the branch pipe 26a, a first open-close valve Va and a first adjustment valve NVa are provided. The first open-close valve Va is a ball valve, for example. The first open-close valve Va can be switched between an open state in which the branch pipe 26a is opened and a close state in which the branch pipe 26a is closed. When the first open-close valve Va is in the open state, a second processing liquid flows through the branch pipe 26a, and the second processing liquid is supplied to the first supply pipe 25 at the first mixing position AA. When the first open-close valve Va is in the close state, the second processing liquid does not flow through the branch pipe 26a. The first adjustment valve NVa can adjust the flow rate of the second processing liquid flowing through the branch pipe 26a. The first adjustment valve NVa is a needle valve, for example.

One end of the branch pipe 26b is connected to the main pipe 26A at the branch point bB, and the other end of the branch pipe 26b is connected to the first supply pipe 25 at the second mixing position BB. In the branch pipe 26b, a second open-close valve Vb and a second adjustment valve NVb are provided. The second open-close valve Vb is a ball valve, for example. The second open-close valve Vb can be switched between an open state in which the branch pipe 26b is opened and a close state in which the branch pipe 26b is closed. When the second open-close valve Vb is in the open state, the second processing liquid flows through the branch pipe 26b, and the second processing liquid is supplied to the first supply pipe 25 at the second mixing position BB. When the second open-close valve Vb is in the close state, the second processing liquid does not flow through the branch pipe 26b. The second adjustment valve NVb can adjust the flow rate of the second processing liquid flowing through the branch pipe 26b. The second adjustment valve NVb is a needle valve, for example.

One end of the branch pipe 26c is connected to the main pipe 26A at the branch point cC, and the other end of the branch pipe 26c is connected to the first supply pipe 25 at the third mixing position CC. In the branch pipe 26c, a third open-close valve Vc and a third adjustment valve NVc are provided. The third open-close valve Vc is a ball valve, for example. The third open-close valve Vc can be switched between an open state in which the branch pipe 26c is opened and a close state in which the branch pipe 26c is closed. When the third open-close valve Vc is in the open state, the second processing liquid flows through the branch pipe 26c, and the second processing liquid is supplied to the first supply pipe 25 at the third mixing position CC. When the third open-close valve Vc is in the close state, the second processing liquid does not flow through the branch pipe 26c. The third adjustment valve NVc can adjust the flow rate of the second processing liquid flowing through the branch pipe 26c. The third adjustment valve NVc is a needle valve, for example.

One end of the branch pipe 26d is connected to the main pipe 26A at the branch point dD, and the other end of the branch pipe 26d is connected to the discharge nozzle 21b at the fourth mixing position DD. In the branch pipe 26d, a fourth open-close valve Vd and a fourth adjustment valve NVd are provided. The fourth open-close valve Vd is a ball valve, for example. The fourth open-close valve Vd can be switched between an open state in which the branch pipe 26d is opened and a close state in which the branch pipe 26d is closed. When the fourth open-close valve Vd is in the open state, the second processing liquid flows through the branch pipe 26d, and the second processing liquid is supplied to the discharge nozzle 21b at the fourth mixing position DD. When the fourth open-close valve Vd is in the close state, the second processing liquid does not flow through the branch pipe 26d. The fourth adjustment valve NVd can adjust the flow rate of the second processing liquid flowing through the branch pipe 26d. The fourth adjustment valve NVd is a needle valve, for example.

The plurality of branch pipes 26a to 26d are an example of a plurality of second supply paths. The branch pipe 26d is an example of a final supply path. The second supplier 23b, and the first open-close valve Va to the fourth open-close valve Vd are examples of a second supplier.

In the first supply pipe 25, a main open-close valve V and a main adjustment valve NV are provided. The main open-close valve V and the main adjustment valve NV are arranged between the first supplier 23a and the first mixing position AA. The main open-close valve V can be switched between an open state in which the first supply pipe 25 is opened and a close state in which the first supply pipe 25 is closed. The main open-close valve V is a ball valve, for example. When the main open-close valve V is in the open state, the first processing liquid flows through the first supply pipe 25. When the main open-close valve V is in the close state, the first processing liquid does not flow through the first supply pipe 25. The main adjustment valve NV can adjust the flow rate of the first processing liquid flowing through the first supply pipe 25. The main adjustment valve NV is a needle valve, for example. The first supplier 23a and the main open-close valve V are examples of a first supplier.

The respective flow-path lengths from the discharge port OH to the respective first mixing position AA to fourth mixing position DD are respectively referred to as flow-path lengths LA to LD. The flow-path length LA from the discharge port OH to the first mixing position AA is the largest, and the flow-path length LD from the discharge port OH to the fourth mixing position DD is the smallest. Further, the flow-path length LB from the discharge port OH to the second mixing position BB is shorter than the flow-path length LA and longer than the flow-path length LD. The flow-path length LC from the discharge port OH to the third mixing position CC is shorter than the flow-path length LB and longer than the flow-path length LD.

In the present embodiment, a stirrer 27 is provided between the first mixing position AA and the second mixing position BB of the first supply pipe 25. An in-line mixer may be used as the stirrer 27, for example. The stirrer 27 is provided in the first supply pipe 25. For example, the stirrer 27 has a spiral shape extending about an axial center parallel to the direction in which the first supply pipe 25 extends. The liquid flowing through the first supply pipe 25 changes its flow direction when colliding with the stirrer 27 and is stirred. Another mixer having a driving mechanism may be used as the stirrer 27.

The processing liquid supplier 23 includes the first supplier 23a and the second supplier 23b. The first supplier 23a includes a pump. The first supplier 23a supplies the first processing liquid to the first supply pipe 25 with a predetermined pressure. The second supplier 23b includes a pump. The second supplier 23b supplies the second processing liquid to the second supply pipe 26 with a predetermined pressure.

Here, the SPM liquid supplied to the upper surface of the substrate W will be described. In the present embodiment, the first processing liquid is a sulfuric acid (H₂SO₄), and the second processing liquid is a hydrogen peroxide solution (H₂O₂). The first supplier 23a supplies a sulfuric acid to the first supply pipe 25, and the second supplier 23b supplies a hydrogen peroxide solution to the second supply pipe 26. The sulfuric acid and the hydrogen peroxide solution are mixed in the nozzle arm 21, so that Caro's acid (H₂SO₅) is generated as the third processing liquid. Therefore, the SPM liquid including Caro's acid is discharged from the discharge nozzle 21b. Caro's acid is effective for stripping a resist film. Caro's acid is generated by a reaction formula (1) of the below-mentioned first chemical reaction. The first chemical reaction is an exothermic reaction. Further, the first chemical reaction efficiently progresses at a temperature equal to or higher than the first temperature. Therefore, when the temperature of the first processing liquid is made equal to or higher than the first temperature, Caro's acid can be efficiently generated. The first temperature is about 170° C.

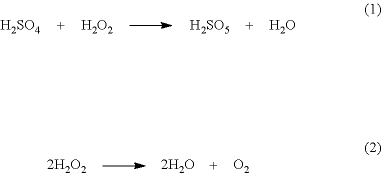

On the other hand, when the temperature of the hydrogen peroxide solution is equal to or higher than a second temperature lower than the first temperature, a second chemical reaction expressed by the above-mentioned reaction formula (2) progresses. The second temperature is about 140° C. The hydrogen peroxide solution is supplied from the branch pipe 26a at the first mixing position AA of the first supply pipe 25. In this case, part of the hydrogen peroxide solution undergoes the first chemical reaction with the sulfuric acid, another part of the hydrogen peroxide solution undergoes the second chemical reaction, and the remaining part of the hydrogen peroxide solution remains without undergoing the first chemical reaction or the second chemical reaction. Therefore, the liquid flowing between the first mixing position AA and the second mixing position BB of the first supply pipe 25 includes a sulfuric acid, a hydrogen peroxide solution, Caro's acid and water. In a period during which the hydrogen peroxide solution flows between the first mixing position AA and the second mixing position BB of the first supply pipe 25, part of the hydrogen peroxide solution may undergo the first chemical reaction with the sulfuric acid, and all of the remaining part of the hydrogen peroxide solution may undergo the second chemical reaction to be broken down into water and oxygen. In this case, the liquid that has reached the second mixing position BB of the first supply pipe 25 does not include a hydrogen peroxide solution but includes a sulfuric acid, Caro's acid and water.

The same applies to the liquid flowing between the second mixing position BB and the third mixing position CC of the first supply pipe 25 and the liquid flowing between the third mixing position CC and the fourth mixing position DD.

In the present embodiment, a hydrogen peroxide solution is supplied to the first supply pipe 25 at each of the first mixing position AA to the fourth mixing position DD. A hydrogen peroxide solution is supplied to each mixing position before a sulfuric acid flows. Therefore, because being supplied to the first supply pipe 25, the sulfuric acid is sequentially mixed with the hydrogen peroxide solution at respective mixing positions, with the mixing starting at the first mixing position AA that is the farthest from the discharge port OH and finishing at the fourth mixing position DD that is the closest to the discharge port OH. The first chemical reaction progresses each time the hydrogen peroxide solution is supplied to the sulfuric acid. As described above, the first chemical reaction is an exothermic reaction. Therefore, the temperature of the liquid flowing through the first supply pipe 25 increases each time the liquid passes through each of the first mixing position AA to the fourth mixing position DD. In other words, the temperature of the liquid passing through the first mixing position AA is the lowest, and the temperature of the liquid passing through the fourth mixing position DD is the highest.

All of the sulfuric acid supplied from the first supplier 23a to the first supply pipe 25 may undergo the first chemical reaction with the hydrogen peroxide solution while flowing through the first supply pipe 25. In this case, a sulfuric acid is not supplied to the discharge nozzle 21b but the SPM liquid including a hydrogen peroxide solution, Caro's acid and water is supplied to the discharge nozzle 21b. Further, in a case in which the remaining portion of the hydrogen peroxide solution that has not undergone the first chemical reaction is broken down by the second chemical reaction before being discharged from the discharge port OH, the hydrogen peroxide solution is not supplied to the discharge nozzle 21b but the SPM liquid including Caro's acid and water is supplied to the discharge nozzle 21b.

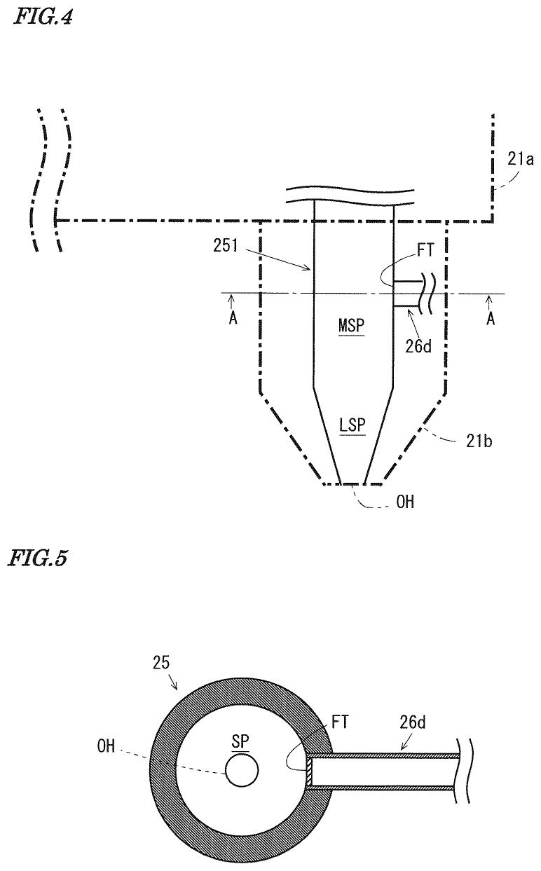

Here, details of the discharge nozzle 21b will be described. FIG. 4 is an enlarged schematic view of the discharge nozzle 21b. FIG. 5 is a cross-sectional view of FIG. 4 taken along the line A-A. The discharge nozzle 21b includes a mixing chamber 251. The mixing chamber 251 is part of the first supply path. The mixing chamber 251 has one end connected to the first supply pipe 25 and the other end leading to the discharge port OH of the discharge nozzle 21b. The mixing chamber 251 includes a columnar mixing space MSP and a coupling space LSP that couples the mixing space MSP to the discharge port OH from below the mixing space MSP. The coupling space LSP has a truncated conical mortar shape in which the cross-sectional area gradually decreases from the mixing space MSP toward the discharge port OH. The branch pipe 26d is connected to the side surface of the mixing space MSP. A filter FT having a plurality of holes is provided at the connecting portion between the branch pipe 26d and the mixing space MSP. The filter FT is a sintered filter, for example. A predetermined pressure is applied to a hydrogen peroxide solution flowing through the branch pipe 26d. Therefore, the hydrogen peroxide solution is supplied to the mixing space MSP in a mist form when passing through the filter FT. Thus, because the hydrogen peroxide solution is in a mist form, the surface area of the hydrogen peroxide solution is increased. As a result, the hydrogen peroxide solution and the sulfuric acid can be efficiently mixed, so that the progress of the first chemical reaction is promoted.

### (3) Substrate Process by Control of Controller 50

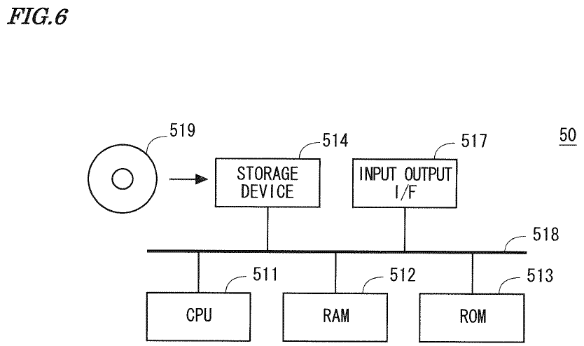

FIG. 6 is a diagram showing one example of the configuration of the controller 50 of FIG. 3. With reference to FIG. 6, the controller 50 includes a CPU 511, a RAM 512, a ROM 513, a storage device 514 and an input-output I/F 517. The CPU 511, the RAM 512, the ROM 513, the storage device 514 and the input-output I/F 517 are connected to a bus 518.

The RAM 512 is used as a work area for the CPU 511. A system program is stored in the ROM 513. The storage device 514 includes a storage medium such as a hard disc or a semiconductor memory and stores a program.

A CD-ROM (compact disc ROM 519) in which a program is recorded is attachable to and detachable from the storage device 514. The CPU 511 loads the program recorded in the hard disc, the semi-conductor memory or the CD-ROM (compact disc) 519 into the RAM 512 and executes the program. The input-output I/F 517 is a communication interface, and can connect the CPU 511 to an external device.

A recording medium storing a program to be executed by the CPU 511 is not limited to the CD-ROM 519. It may be an optical disc (MO (Magnetic Optical Disc)/MD (Mini Disc)/DVD (Digital Versatile Disc)), an IC card, an optical card, and a semiconductor memory such as a mask ROM or an EPROM (Erasable Programmable ROM). Further, the CPU 511 may download the program from a computer connected to the network and store the program in the storage device 514, or the computer connected to the network may write the program in the storage device 514, and the program stored in the storage device 514 may be loaded into the RAM 512 and executed in the CPU 511. The program referred to here includes not only a program directly executable by the CPU 111 but also a source program, a compressed program, an encrypted program and the like.

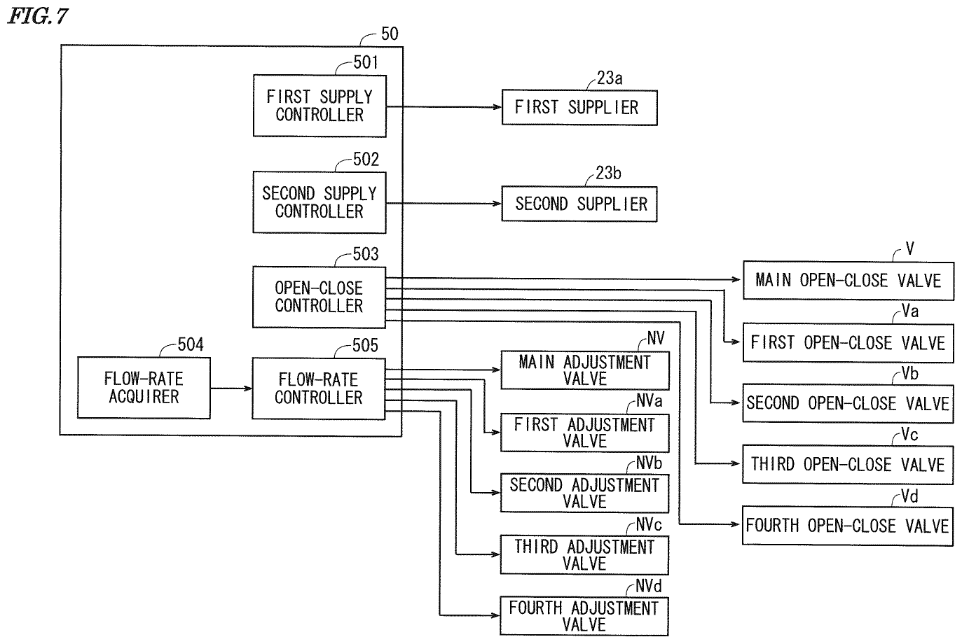

FIG. 7 is a diagram showing one example of the functional configuration of the controller 50. The controller 50 includes a first supply controller 501, a second supply controller 502, an open-close controller 503, a flow-rate acquirer 504 and a flow-rate controller 505. In the present embodiment, the respective constituent elements of the controller 50 are implemented by execution of a substrate processing program stored in the CD-ROM 519 by the CPU 511 of FIG. 6.

The first supply controller 501 controls the first supplier 23a. Specifically, the first supply controller 501 switches the pump (not shown) included in the first supplier 23a between an OFF state and an ON state. When the pump is switched from the OFF state to the ON state, a sulfuric acid supplied to the first supply pipe 25 is pressurized. The second supply controller 502 controls the second supplier 23b. Specifically, the second supply controller 502 switches the pump (not shown) included in the second supplier 23b between an OFF state and an ON state. When the pump is switched from the OFF state to the ON state, a hydrogen peroxide solution supplied to the second supply pipe 26 is pressurized.

The open-close controller 503 controls the main open-close valve V, the first open-close valve Va, the second open-close valve Vb, the third open-close valve Vc and the fourth open-close valve Vd. The open-close controller 503 switches the main open-close valve V between an open state and a close state. When the close state is switched to the open state, a sulfuric acid is supplied to the first supply pipe 25 with a predetermined pressure. The open-close controller 503 switches the first open-close valve Va between an open state and a close state. When the first open-close valve Va is switched from the close state to the open state, a hydrogen peroxide solution is supplied to the first mixing position AA of the first supply pipe 25. The open-close controller 503 switches the second open-close valve Vb between an open state and a close state. When the second open-close valve Vb is switched from the close state to the open state, a hydrogen peroxide solution is supplied to the second mixing position BB of the first supply pipe 25. The open-close controller 503 switches the third open-close valve Vc between an open state and a close state. When the third open-close valve Vc is switched from the close state to the open state, a hydrogen peroxide solution is supplied to the third mixing position CC of the first supply pipe 25. The open-close controller 503 switches the fourth open-close valve Vd between an open state and a close state. When the fourth open-close valve Vd is switched from the close state to the open state, a hydrogen peroxide solution is supplied to the fourth mixing position DD of the discharge nozzle 21b. After switching the main open-close valve V from the close state to the open state, the open-close controller 503 switches the first open-close valve Va to the fourth open-close valve Vd from the close state to the open state at the same time.

The flow-rate acquirer 504 acquires the flow rate of a sulfuric acid to flow through the first supply pipe 25 and the flow rate of a hydrogen peroxide solution to be supplied from each branch pipe to the first supply pipe 25 at each of the first mixing position AA to the fourth mixing position DD. In the present embodiment, the flow rate of a sulfuric acid to flow through the first supply pipe 25 and the flow rate of a hydrogen peroxide solution to be supplied from each branch pipe to the first supply pipe 25 at each of the first mixing position AA to the fourth mixing position DD are determined in advance and stored in the storage device 514 of FIG. 6. The flow rate of a sulfuric acid to flow through the first supply pipe 25 is a main flow rate. Further, the flow rates of a hydrogen peroxide solution to be supplied from the second supply pipe 26 at the respective mixing position are a first flow rate at the first mixing position AA, a second flow rate at the second mixing position BB, a third flow rate at the third mixing position CC, and a fourth flow rate at the fourth mixing position DD. The flow-rate acquirer 504 acquires each flow rate stored in the storage device 514.

In the present embodiment, the flow rate of a hydrogen peroxide solution supplied to the discharge nozzle 21b at the fourth mixing position DD is larger than the flow rate of a hydrogen peroxide solution supplied from the branch pipe 26c to the first supply pipe 25 at the third mixing position CC, the flow rate of a hydrogen peroxide solution supplied from the branch pipe 26b to the first supply pipe 25 at the second mixing position BB, and the flow rate of a hydrogen peroxide solution supplied from the branch pipe 26a to the first supply pipe 25 at the first mixing position AA. In other words, the flow rate of a hydrogen peroxide solution supplied to the discharge nozzle 21b at the fourth mixing position DD having the shortest flow-path length from the discharge port OH is the largest.

Based on each flow rate acquired by the flow-rate acquirer 504, the flow-rate controller 505 controls the main adjustment valve NV, the first adjustment valve NVa, the second adjustment valve NVb, the third adjustment valve NVc and the fourth adjustment valve NVd. Specifically, the flow-rate controller 505 controls the main adjustment valve NV to make the flow rate of a sulfuric acid to be supplied to the first supply pipe 25 be equal to the flow rate (main flow rate) acquired in regard to the first supply pipe 25 by the flow-rate acquirer 504. The flow-rate controller 505 controls the first adjustment valve NVa to make the flow rate of a hydrogen peroxide solution to be supplied to the first supply pipe 25 at the first mixing position AA be equal to the flow rate (first flow rate) acquired in regard to the first mixing position AA by the flow-rate acquirer 504. The flow-rate controller 505 controls the second adjustment valve NVb to make the flow rate of a hydrogen peroxide solution to be supplied to the first supply pipe 25 at the second mixing position BB be equal to the flow rate (second flow rate) acquired in regard to the second mixing position BB by the flow-rate acquirer 504. The flow-rate controller 505 controls the third adjustment valve NVc to make the flow rate of a hydrogen peroxide solution to be supplied to the first supply pipe 25 at the third mixing position CC be equal to the flow rate (third flow rate) acquired in regard to the third mixing position CC by the flow-rate acquirer 504. The flow-rate controller 505 controls the fourth adjustment valve NVd to make the flow rate of a hydrogen peroxide solution to be supplied to the discharge nozzle 21b at the fourth mixing position DD be equal to the flow rate (fourth flow rate) acquired in regard to the fourth mixing position DD by the flow-rate acquirer 504.

Further, for example, a flow-rate sensor that detects the flow rate of liquid flowing through the first supply pipe 25 may be provided at a position farther downstream than the main adjustment valve NV of the first supply pipe 25. In this case, after switching the main open-close valve V to the open state, the flow-rate controller 505 executes feedback control of the main adjustment valve NV based on a flow rate detected by the flow-rate sensor. The same applies to the first adjustment valve NVa, the second adjustment valve NVb, the third adjustment valve NVc and the fourth adjustment valve NVd.

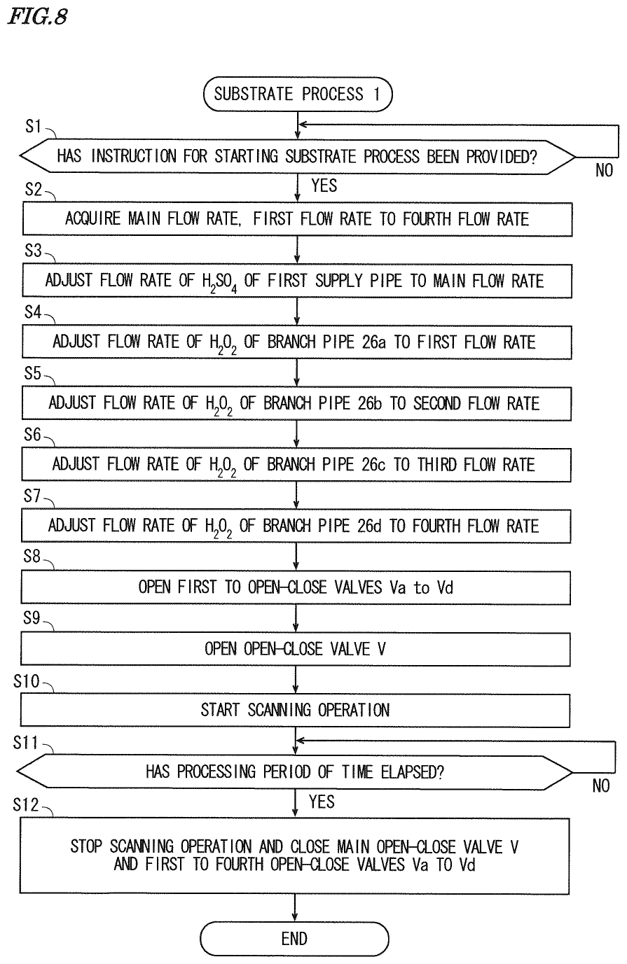

FIG. 8 is a flowchart for explaining one example of a flow of a substrate process. The substrate process is a process executed by the CPU 511 included in the controller 50 when the CPU 511 executes the substrate processing program stored in the RAM 512. Here, the substrate process for one substrate W will be described. The substrate process described here is a process of discharging the SPM liquid toward the substrate W in a period during which the substrate W held on the spin base 11 by the spin chuck 10 is rotated by a predetermined number of rotations. A period of time required for the substrate process to be executed on one substrate W is referred to as a processing period of time. The processing period of time is a predetermined period of time. The processing period of time is stored in the storage device 514 of FIG. 6. At the start of the substrate process, the main open-close valve V, the first open-close valve Va, the second open-close valve Vb, the third open-close valve Vc and the fourth open-close valve Vd are in the close state. Further, before the substrate process is started, the discharge arm 21a having the discharge nozzle 21b is arranged at a waiting position at the outer periphery of the splash guard 40.

With reference to FIG. 8, the CPU 511 included in the controller 50 determines whether the substrate process has been started (step S1). A point in time at which the substrate W rotated by the spin chuck 10 reaches a predetermined number of rotations is detected as a start point in time of the substrate process. The CPU 511 moves the discharge nozzle 21b from the waiting position to a position above the substrate. The CPU 511 waits until the start of the substrate process is detected. When the start of the substrate process is detected, the process proceeds to the step S2.

In the step S2, the CPU 511 acquires the main flow rate, the first flow rate, the second flow rate, the third flow rate and the fourth flow rate, and the process proceeds to the step S3. Here, the main flow rate, the first flow rate, the second flow rate, the third flow rate and the fourth flow rate stored in the storage device 514 are read. In the step S3, the CPU 511 provides an electrical signal indicating the main flow rate acquired in the step S2 to the main adjustment valve NV, and the process proceeds to the step S4. Thus, the main adjustment valve NV is adjusted to have an opening (a degree of opening) that causes the flow rate of a sulfuric acid flowing from the first supply pipe 25 toward the discharge port OH to be the main flow rate.

In the step S4, the CPU 511 provides an electrical signal indicating the first flow rate acquired in the step S2 to the first adjustment valve NVa, and the process proceeds to the step S5. Thus, the first adjustment valve NVa is adjusted to have an opening that causes the flow rate of a hydrogen peroxide solution flowing from the branch pipe 26a toward the first mixing position AA to be the first flow rate.

In the step S5, the CPU 511 provides an electrical signal indicating the second flow rate acquired in the step S2 to the second adjustment valve NVb, and the process proceeds to the step S6. Thus, the second adjustment valve NVb is adjusted to have an opening that causes the flow rate of a hydrogen peroxide solution flowing from the branch pipe 26b toward the second mixing position BB to be the second flow rate. In the step S6, the CPU 511 provides an electrical signal indicating the third flow rate acquired in the step S2 to the third adjustment valve NVc, and the process proceeds to the step S7. Thus, the third adjustment valve NVc is adjusted to have an opening that causes the flow rate of a hydrogen peroxide solution flowing from the branch pipe 26b toward the third mixing position CC to be the third flow rate. In the step S7, the CPU 511 provides an electrical signal indicating the fourth flow rate acquired in the step S2 to the fourth adjustment valve NVd, and the process proceeds to the step S8. Thus, the fourth adjustment valve NVd is adjusted to have an opening that causes the flow rate of a hydrogen peroxide solution flowing from the branch pipe 26d toward the fourth mixing position DD to be the fourth flow rate.

In the step S8, the CPU 511 opens the first open-close valve Va, the second open-close valve Vb, the third open-close valve Vc and the fourth open-close valve Vd at the same time. In this case, a hydrogen peroxide solution is supplied at the predetermined flow rates (first flow rate to fourth flow rate) to the first mixing position AA to the fourth mixing position DD of the first supply pipe 25. In the step S9, the CPU 511 opens the main open-close valve V. A sulfuric acid is supplied at a predetermined flow rate (main flow rate) to the first supply pipe 25 to which the hydrogen peroxide solution has been supplied in advance. In this case, the sulfuric acid is sequentially mixed with the hydrogen peroxide solution, with the mixing starting at the first mixing position AA that is the farthest from the discharge port OH and finishing at the fourth mixing position DD that is the closest to the discharge port OH. The main open-close valve V may be opened at any point in time as long as it is after the second processing liquid in each branch pipe is supplied to each mixing position of the first supply pipe 25. In the step S10, the CPU 511 starts the scanning operation of the discharge nozzle 21b. Thus, the discharge port OH of the discharge nozzle 21b is moved on the movement line YL above the substrate W while the SPM liquid is discharged from the discharge port OH of the discharge nozzle 21b.

In the step S11, the CPU 511 determines whether the predetermined processing period of time has elapsed since the start of the substrate process. The process waits until the processing period of time elapses. The process proceeds to the step S12 when the processing period of time elapses. Until the processing period of time elapses, the discharge port OH of the discharge nozzle 21b is moved in a horizontal direction above the substrate W while the SPM liquid is discharged from the discharge port OH of the discharge nozzle 21b. In the step S12, the CPU 511 ends the substrate process. Specifically, the CPU 511 stops the scanning operation of the discharge nozzle 21b, and switches the main open-close valve V, the first open-close valve Va, the second open-close valve Vb, the third open-close valve Vc and the fourth open-close valve Vd to the close state at the same time.

Here, the state of liquid in the first supply pipe 25 during execution of the substrate process will be described. The sulfuric acid flowing through the first supply pipe 25 from the first supplier 23a toward the discharge port OH is mixed with the hydrogen peroxide solution supplied from the branch pipe 26a at the first mixing position AA. Thereafter, between the first mixing position AA and the second mixing position BB of the first supply pipe 25, part of the sulfuric acid and the hydrogen peroxide solution undergo the first chemical reaction expressed by the above-mentioned formula (1), and Caro's acid is generated.

The stirrer 27 is provided between the first mixing position AA and the second mixing position BB of the first supply pipe 25. At the entrance of the stirrer 27, the temperature of the sulfuric acid is 170° C., and the temperature of the hydrogen peroxide solution is a room temperature. Therefore, the sulfuric acid and the hydrogen peroxide solution are both liquid. Therefore, the sulfuric acid and the hydrogen peroxide solution are efficiently stirred by the stirrer 27.

Further, between the first mixing position AA and the second mixing position BB of the first supply pipe 25, the second chemical reaction expressed by the above-mentioned formula (2) progresses at the same time as the progress of the first chemical reaction expressed by the above-mentioned formula (1). Thus, water and oxygen are generated. The first chemical reaction expressed by the formula (1) is an exothermic reaction. Therefore, when the temperature of the liquid flowing between the first mixing position AA and the second mixing position BB becomes equal to or higher than a boiling point of water, water included in the liquid is vaporized. Therefore, the mixture of liquid and gas is present between the first mixing position AA and the second mixing position BB.

The sulfuric acid that has not undergone the first chemical reaction with the hydrogen peroxide solution between the first mixing position AA and the second mixing position BB of the first supply pipe 25, and the Caro's acid flow toward the second mixing position BB. The sulfuric acid that has not undergone the first chemical reaction with the hydrogen peroxide solution supplied from the branch pipe 26b at the second mixing position BB of the first supply pipe 25 are joined with the Caro's acid. In this case, between the second mixing position BB and the third mixing position CC of the first supply pipe 25, part of the sulfuric acid and the hydrogen peroxide solution undergo the first chemical reaction expressed by the above-mentioned formula (1), and Caro's acid is generated.

Next, the sulfuric acid that has not undergone the first chemical reaction with the hydrogen peroxide solution between the second mixing position BB and the third mixing position CC of the first supply pipe 25, and the Caro's acid flow toward the third mixing position CC. The sulfuric acid that has not undergone the first chemical reaction with the hydrogen peroxide solution supplied from the branch pipe 26c at the third mixing position CC of the first supply pipe 25 is joined with the Caro's acid. In this case, between the third mixing position CC and the fourth mixing position DD of the first supply pipe 25, part of the sulfuric acid and the hydrogen peroxide solution undergo the first chemical reaction expressed by the above-mentioned formula (1), and Caro's acid is generated.

Next, the sulfuric acid that has not undergone the first chemical reaction with the hydrogen peroxide solution between the third mixing position CC and the fourth mixing position DD of the first supply pipe 25, and the Caro's acid flow toward the fourth mixing position DD. The sulfuric acid that has not undergone the first chemical reaction with the hydrogen peroxide solution supplied from the branch pipe 26d at the fourth mixing position DD of the discharge nozzle 21b is joined with the Caro's acid. In this case, the sulfuric acid and the hydrogen peroxide solution are mixed in the mixing space MSP between the fourth mixing position DD of the discharge nozzle 21b and the discharge port OH. Thus, the sulfuric acid and the hydrogen peroxide solution undergo the first chemical reaction expressed by the above-mentioned formula (1), and Caro's acid is generated. Finally, the SPM liquid including Caro's acid is supplied from the discharge port OH to the upper surface of the substrate W.

### (4) Effects of Embodiment

The first mixing position AA to the fourth mixing position DD of the first supply pipe 25 have different flow-path lengths to the discharge port OH. Because a hydrogen peroxide solution is supplied at the respective first mixing position AA to fourth mixing position DD of the first supply pipe 25, the hydrogen peroxide solution can be mixed with a sulfuric acid flowing through the first supply pipe 25 at a plurality of different points in time at respective mixing positions. Further, the ratio of an amount of the hydrogen peroxide solution with respect to an amount of the sulfuric acid present at each of the first mixing position AA to the fourth mixing position DD can be set equal to or larger than a predetermined ratio, and it is possible to cause the first chemical reaction to progress at the plurality of different points in time. Therefore, it is possible to reduce the usage amount of the hydrogen peroxide solution while causing the first chemical reaction to efficiently progress. As a result, it is possible to provide the substrate processing apparatus capable of reducing the consumption of the chemical liquid to be used.

Further, the hydrogen peroxide solution is supplied to the first supply pipe 25 at a maximum flow rate at the fourth mixing position DD that is the closest to the discharge port OH. Thus, the hydrogen peroxide solution is mixed at the maximum flow rate with the sulfuric acid having the highest temperature, so that Caro's acid can be efficiently generated.

The sulfuric acid and the hydrogen peroxide solution in the first supply pipe 25 are stirred by the stirrer 27, so that it is possible to increase the contact area between the sulfuric acid and the hydrogen peroxide solution. This can promote the progress of the first chemical reaction between the sulfuric acid and the hydrogen peroxide solution at the first mixing position AA.

### (5) Inventive Examples and Comparative Examples

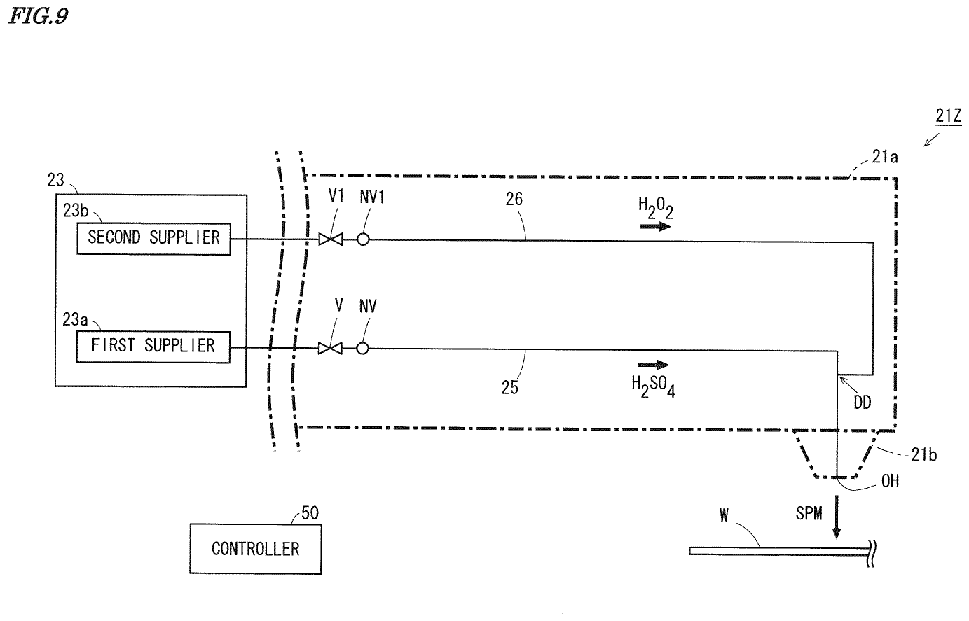

Two experiments were conducted to compare the performance for stripping a resist film off the substrate W by the substrate processing apparatus 100 according to the present embodiment. Here, a first experiment will be described. In the inventive example, the substrate processing apparatus 100 having the nozzle arm 21 of FIG. 3 was used. FIG. 9 is a schematic diagram for explaining a nozzle arm 21Z of a substrate processing apparatus 100 used in a first comparative example. Differences between the nozzle arm 21 of FIG. 3 and the nozzle arm 21Z of FIG. 9 are described below. A second supply pipe 26 of the nozzle arm 21Z does not branch and is connected to a first supply pipe 25 at a fourth mixing position DD. The second supply pipe 26 includes a sub-open-close valve V1 and a sub-adjustment valve NV1. The functions of the sub-open-close valve V1 and the sub-adjustment valve NV1 are similar to those of the functions of the main open-close valve V and the main adjustment valve NV. In the nozzle arm 21Z of the first comparative example, a hydrogen peroxide solution is mixed, at one location, with a sulfuric acid flowing through the first supply pipe 25.

In the first experiment, the inventive example and the first comparative example were compared to each other in regard to performance for stripping a resist film. In the first experiment, a substrate process was executed with each of the nozzle arm 21 of the inventive example and the nozzle arm 21Z of the first comparative example being stopped above the upper surface of the substrate W on the spin chuck 10. The ratio of a sulfuric acid flowing through the first supply pipe 25 to a hydrogen peroxide solution flowing through the second supply pipe 26 in each of the nozzle arm 21 of the inventive example and the nozzle arm 21Z of the first comparative example was adjusted to 10:1. Further, the number of rotations of the substrate W held by the spin chuck 10 was set to 200 rpm.

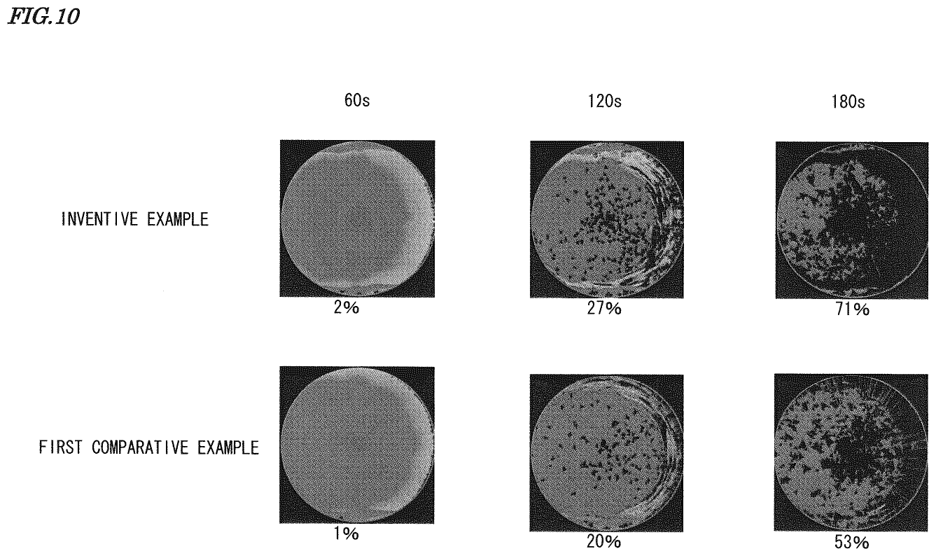

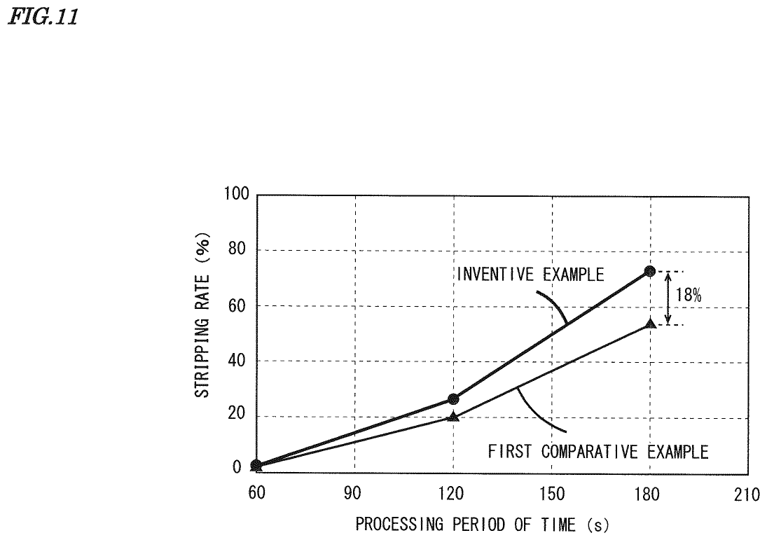

FIG. 10 is a first diagram showing the result of the first experiment, and FIG. 11 is a second diagram showing the result of a second experiment. FIG. 10 shows images of the obverse surface of the substrate W after the substrate process is executed in the inventive example and the first comparative example. Here, an SPM liquid is supplied to the obverse surface of the substrate W for 60 seconds, the SPM liquid is supplied to the obverse surface of the substrate W for 120 seconds, and the SPM liquid is supplied to the obverse surface of the substrate W for 180 seconds, by way of example. In each image for each substrate, the stripping state of the resist film on the substrate W is shown by shading. Specifically, the portion in the substrate W where the resist film has been completely stripped is indicated in black, and the portion of the substrate W where stripping of the resist film is in progress is indicated by light color having a lower density than that of black. The further the stripping has progressed, the higher the density. The numbers indicated below the plurality of images indicate the stripping rates. The stripping rate is the ratio of the total area where the stripping of the resist film is completed to the area of the upper surface of the substrate W. FIG. 11 is a graph showing the stripping rate of each of the inventive example and the first comparative example of FIG. 10. The ordinate of the graph of FIG. 11 indicates a stripping rate (%) of the resist film, and the abscissa indicates a processing period of time.

In a case in which the SPM liquid was supplied to the obverse surface of the substrate W for 60 seconds, the stripping rate of the resist film was 2% in the inventive example, whereas the stripping rate of the resist film was 1% in the first comparative example. In a case in which the SPM liquid was supplied to the obverse surface of the substrate W for 120 seconds, the stripping rate of the resist film was 27% in the inventive example, whereas the stripping rate of the resist film was 20% in the first comparative example. In a case in which the SPM liquid was supplied to the obverse surface of the substrate W for 180 seconds, the stripping rate of the resist film was 71% in the inventive example, whereas the stripping rate of the resist film was 53% in the first comparative example.

According to the results of this experiment, the longer the processing period of time, the higher the stripping rate, in either of the inventive example 1 and the first comparative example. However, even with the same processing period of time, the stripping rate of the inventive example is higher than the stripping rate of the first comparative example. In particular, in a case in which the SPM liquid was supplied to the obverse surface of the substrate W for 180 seconds, it was found that the stripping rate of the resist film in the nozzle arm 21 of the example was improved by 18% as compared with the nozzle arm 21Z of the first comparative example. As described above, since the stripping rate of the resist film in the nozzle arm 21 of the inventive example was improved as compared to the nozzle arm 21Z of the first comparative example, it was confirmed that it was effective for a hydrogen peroxide solution to join a sulfuric acid flowing through the first supply pipe 25 in multiple stages as in the nozzle arm 21.

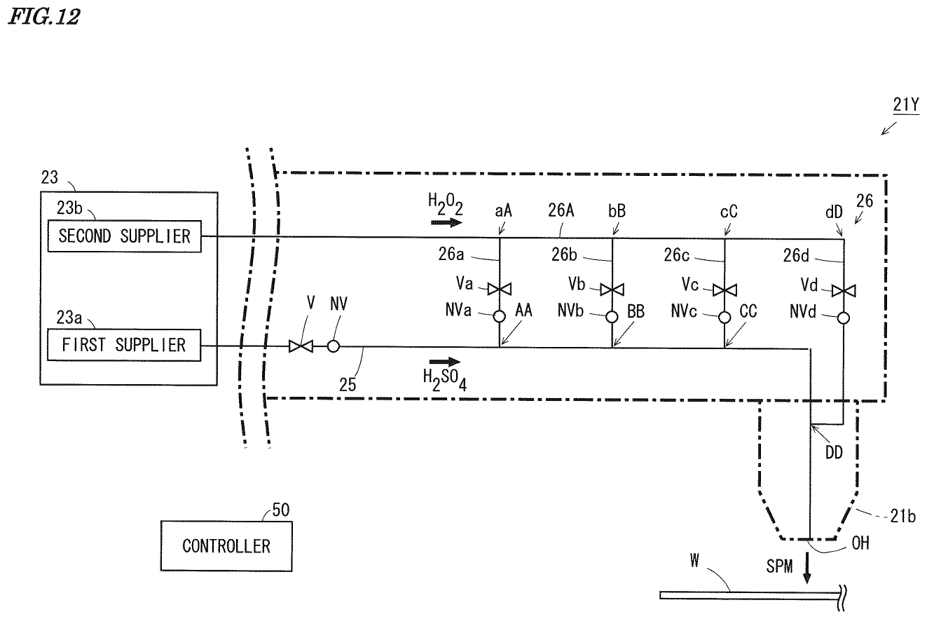

Next, the second experiment will be described. In the inventive example, the substrate processing apparatus 100 having the nozzle arm 21 of FIG. 3 was used. FIG. 12 is a schematic diagram for explaining a nozzle arm 21Y of a substrate processing apparatus 100 used in a second comparative example. The difference between the nozzle arm 21 of FIG. 3 and the nozzle arm 21Z of FIG. 9 is that the stirrer 27 is not provided in the nozzle arm 21Y.

In the second experiment, the inventive example and the second comparative example were compared in regard to a stripping amount of a resist film. In the second experiment, a substrate process was executed with each of the nozzle arm 21 of the inventive example and the nozzle arm 21Y of the second comparative example being stopped above the upper surface of the substrate W on the spin chuck 10. The ratio of a sulfuric acid flowing through the first supply pipe 25 to a hydrogen peroxide solution flowing through the second supply pipe 26 in each of the nozzle arm 21 of the inventive example and the nozzle arm 21Y of the second comparative example was adjusted to 4:1. The substrate W having the radius of 300 mm was used. Further, in the second experiment, an SPM liquid was discharged from the discharge nozzle 21b with the discharge nozzle 21b fixed at a position above the center of the substrate W.

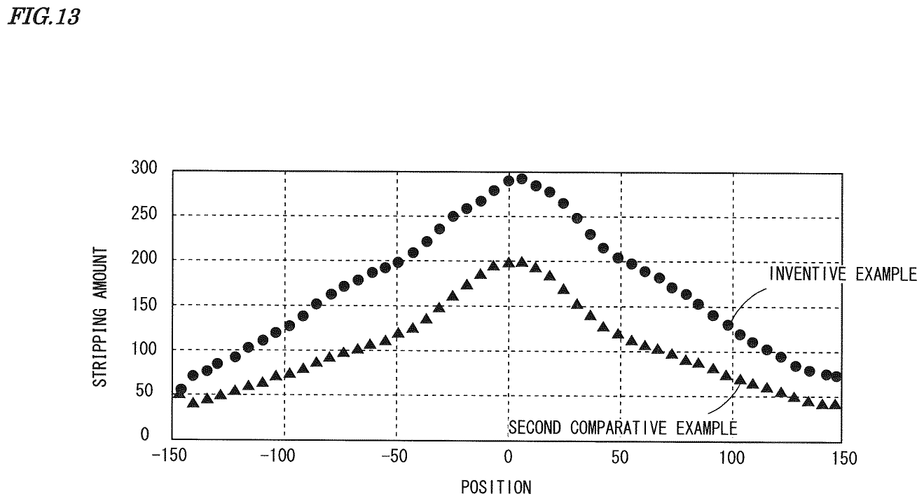

FIG. 13 is a diagram showing the result of the second experiment. The ordinate of the graph of FIG. 13 indicates a stripping amount of a resist film, and the abscissa indicates a position in a radial direction in one cross section of the substrate W. 0 mm in the abscissa indicates the center of the substrate, and −150 mm and 150 mm in the abscissa indicate both ends of the substrate in one cross section. In the graph of FIG. 13, the stripping amounts of the resist film at a plurality of respective positions in the radial direction in one cross section of each of the substrates W on which the substrate process has been executed in the inventive example and the second comparative example are plotted. Since the substrate process was executed with each of the nozzle arm 21 of the inventive example and the nozzle arm 21Y of the second comparative example being stopped on the upper surface of the substrate W on the spin chuck 10, the portion having the largest stripping amount is located near 0 mm on the abscissa. In the second experiment, as shown in FIG. 13, it was found that, as a whole, the stripping amount of the resist film of the inventive example was larger than the stripping amount of the resist film of the second comparative example. In this manner, it was confirmed that, when the stirrer 27 was provided in the first supply pipe 25 of the nozzle arm 21, the stripping amount of the resist film was improved.

### First Modified Example

In the above-mentioned embodiment, the main open-close valve V is opened after the second processing liquid in each branch pipe is supplied to each mixing position of the first supply pipe 25. However, the present disclosure is not limited to this. The main open-close valve V and the open-close valve arranged in each branch pipe may be opened at the same time. In this case, the length of the pipe from each open-close valve arranged in each branch pipe to each mixing position of the first supply pipe 25 is set such that, when the main open-close valve V and each of the valves Va to Vd arranged at each of the branch pipes 26a to 26d are opened at the same time, the second processing liquid is supplied from each of the branch pipes 26a to 26d to each of the mixing positions AA to DD of the first supply pipe 25 earlier than the supply of the first processing liquid to each of the mixing positions. In this case, at the start of the substrate process, the second processing liquid is discharged before the SPM liquid is discharged from the discharge port OH.

In the above-mentioned embodiment, the first processing liquid (sulfuric acid) is supplied to the second processing liquid (hydrogen peroxide solution) that has been supplied to each mixing position of the first supply pipe 25 in advance. Therefore, the first processing liquid is sequentially mixed with the second processing liquid, with the mixing starting at the first mixing position AA that is the farthest from the discharge port OH and finishing at the fourth mixing position DD that is the closest to the discharge port OH, by way of example. However, the present disclosure is not limited to this. In a state in which the first processing liquid is supplied to each mixing position, the second processing liquid may be sequentially supplied to the first processing liquid that has flown through the first supply pipe. The state in which the first processing liquid is supplied to each mixing position may be the state in which the first processing liquid is supplied to each mixing position in advance or the state in which the first processing liquid and the second processing liquid are supplied to each mixing position at the same time. In this case, at the start of the substrate process, the first processing liquid is discharged before the SPM liquid is discharged from the discharge port OH.

As the configuration for adjusting a point in time at which the second processing liquid is supplied to each mixing position, the first open-close valve Va to the fourth open-close valve Vd are made to be opened and closed at different points in time. In the first modified example, the CPU 511 first opens the main open-close valve V and supplies the first processing liquid to the first supply pipe 25. Next, the CPU 511 controls the first open-close valve Va to the fourth open-close valve Vd such that, with the first processing liquid supplied to each mixing position, the second processing liquid is supplied to each mixing position. In other words, the first open-close valve Va to the fourth open-close valve Vd corresponding to the first mixing position AA that is the farthest from the discharge port OH to the fourth mixing position DD that is the closest to the discharge port OH are sequentially opened. With the present configuration, the second processing liquid is sequentially mixed with the first processing liquid at respective mixing positions.

### Second Modified Example

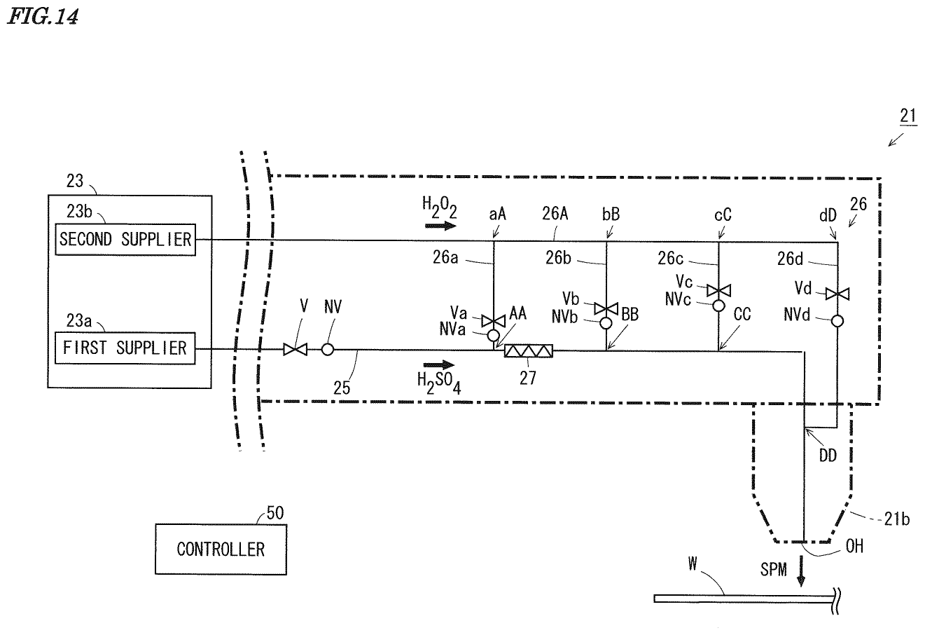

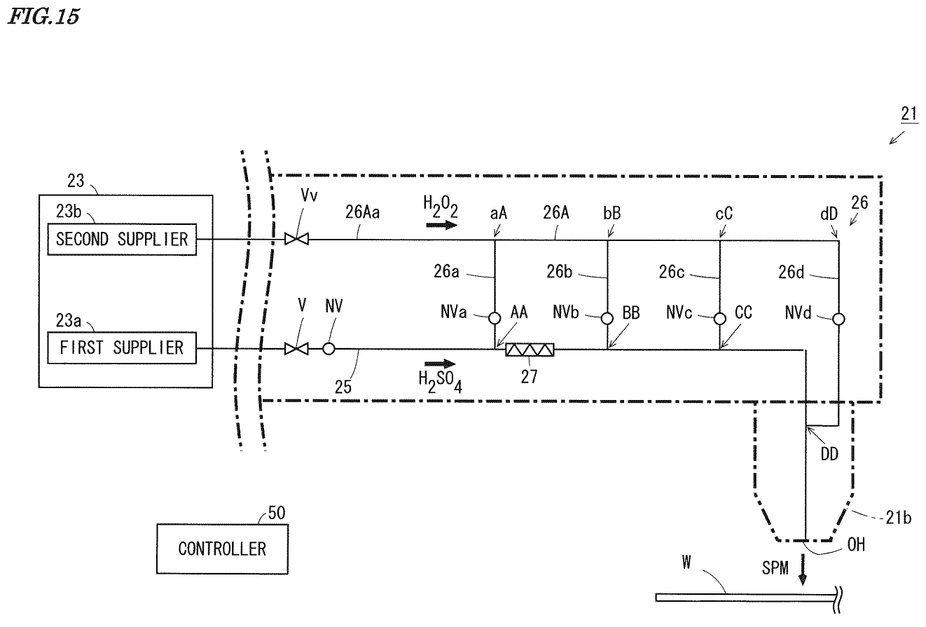

In a second modified example which is another configuration for adjusting the points in time at which the second processing liquid is supplied to the respective mixing positions, the distances from the respective open-close valves arranged in the respective branch pipes to the respective mixing positions of the first supply pipe 25 are made different, and the open-close valves are opened at the same time. FIG. 14 is a first schematic diagram for explaining a nozzle arm of a substrate processor of the second modified example. More specifically, in order to supply the second processing liquid to each mixing position with the first processing liquid that has flown through the first supply pipe being supplied to each mixing position, the nozzle arm is configured such that the longer the pipe from the discharge port OH to each mixing position, the shorter the length of the pipe from each open-close valve arranged at each branch pipe to the mixing position. As shown in FIG. 14, the flow-path length from the first open-close valve Va of the branch pipe 26a to the first mixing position AA, the flow-path length from the second open-close valve Vb of the branch pipe 26b to the second mixing position BB, the flow-path length from the third open-close valve Vc of the branch pipe 26c to the third mixing position CC, and the flow-path length from the fourth open-close valve Vd of the branch pipe 26d to the fourth mixing position DD are different. The flow-path length from the first open-close valve Va of the branch pipe 26a to the first mixing position AA is the longest, the flow-path length from the second open-close valve Vb of the branch pipe 26b to the second mixing position BB is the second longest, the flow-path length from the third open-close valve Vc of the branch pipe 26c to the third mixing position CC is the third longest, and the flow-path length from the fourth open-close valve Vd of the branch pipe 26d to the fourth mixing position DD is the shortest. With the present configuration, the CPU 511 is configured such that, when the main open-close valve V and the first open-close valve Va to the fourth open-close valve Vd are controlled to be opened at the same time, the second processing liquid is supplied to each mixing position with the first processing liquid that has flown through the first supply pipe 25 being supplied to each mixing position. Therefore, the second processing liquid is sequentially mixed with the first processing liquid at each mixing position.

According to the two modified examples, described above, the hydrogen peroxide solution can be mixed with the sulfuric acid flowing through the first supply pipe 25 at a plurality of different points in time at respective mixing positions. Further, the ratio of an amount of the hydrogen peroxide solution with respect to an amount of the sulfuric acid present at each of the first mixing position AA to the fourth mixing position DD can be set equal to or larger than a predetermined ratio, and it is possible to cause the first chemical reaction to progress at the plurality of different points in time. Therefore, it is possible to reduce the usage amount of the hydrogen peroxide solution while causing the first chemical reaction to efficiently progress. As a result, it is possible to provide the substrate processing apparatus capable of reducing the consumption of the chemical liquid to be used.

### Third Modified Example

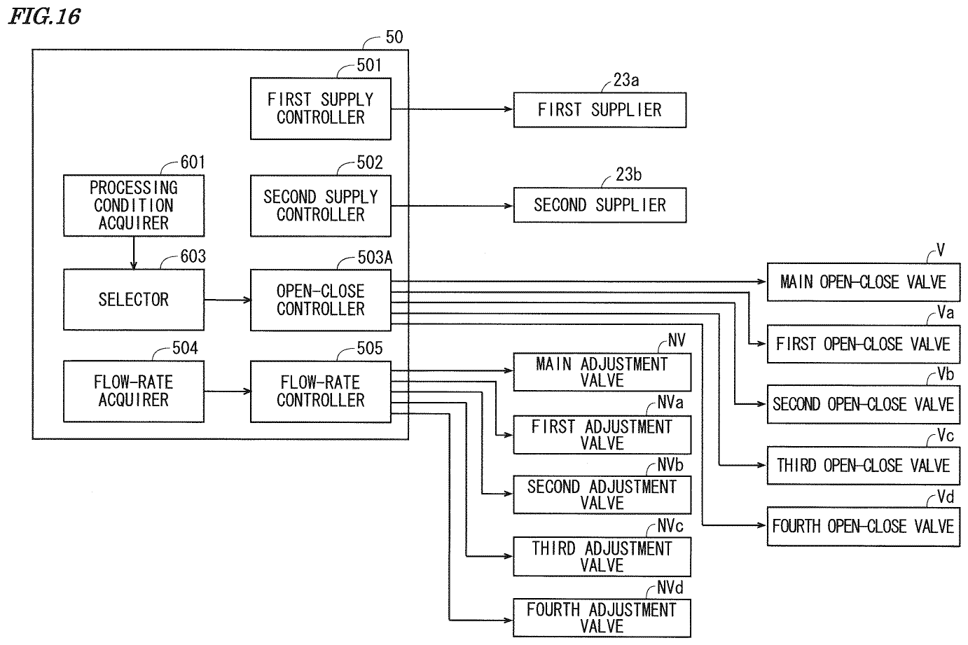

FIG. 15 is a second schematic diagram for explaining a nozzle arm of a substrate processor of a third modified example. In the nozzle arm 21 of FIG. 15, first to fourth open-close valves Va to Vd are not provided in branch pipes 26a to 26d, respectively. A main pipe 26A of a second supply pipe 26 includes a connection path 26Aa. The connection path 26Aa is provided between a second supplier 23b and each of branch pipes 26a to 26d. A switching valve Vv is provided in the connection path 26Aa. The switching valve Vv switches between supply of a second processing liquid and stop of supply of a second processing liquid in regard to the second supplier 23bg to the branch pipes 26a to 26d. The flow-path length from the switching valve Vv to the first mixing position AA is the shortest, the flow-path length from the switching valve Vv to the second mixing position BB is the second shortest, the flow-path length from the switching valve Vv to the third mixing position CC is the third shortest, and the flow-path length from the switching valve Vv to the fourth mixing position DD is the longest. In this case, in a case in which the CPU 511 switches the switching valve Vv to the open state in which the second processing liquid is supplied from the second supplier 23b to each of the branch pipes 26a to 26d, the second processing liquid reaches the first mixing position AA, the second mixing position BB, the third mixing position CC and the fourth mixing position DD in this order. In this manner, the periods of time required until the second processing liquid reaches the respective mixing positions can be made different.

### Fourth Modified Example

In the first modified example, one of the first processing liquid and the second processing liquid reaches the plurality of mixing positions first at the start of the substrate processing, by way of example. However, the first processing liquid and the second processing liquid may reach the plurality of mixing positions at the same time. As described in the first modified example, in order to adjust the points in time at which the first processing liquid and the second processing liquid reach the plurality of mixing positions, the main open-close valve V, and the first open-close valve Va to the fourth open-close valve Vd may be respectively opened and closed at different points in time. Alternatively, as described in the second modified example, in order to adjust the points in time at which the first processing liquid and the second processing liquid reach the plurality of mixing positions, the respective distances from the main open-close valve V, and the first open-close valve Va to the fourth open-close valve Vd to the respective mixing positions of the first supply pipe 25 may be made different. In this case, at the start of the substrate process, the SPM liquid can be discharged from the discharge port OH. As a result, the first processing liquid and the second processing liquid can be efficiently mixed, and the consumption of the first processing liquid and the second processing liquid can be suppressed.

### Fifth Modified Example

While the first processing liquid is a sulfuric acid and the second processing liquid is a hydrogen peroxide solution, the present disclosure is not limited to this. The first processing liquid may be a hydrogen peroxide solution, and the second processing liquid may be a sulfuric acid. While the combination of the first processing liquid and the second processing liquid is the combination of a sulfuric acid and a hydrogen peroxide solution by way of example, the present disclosure is not limited to this. The combination of the first processing liquid and the second processing liquid is only required to satisfy the condition that at least one of the first processing liquid and the second processing liquid undergoes, at a temperature equal to or higher than a predetermined temperature, a chemical reaction in which the one of the first processing liquid and the second processing liquid is broken down, and the condition that a chemical reaction that progresses when the first processing liquid and the second processing liquid are mixed is an exothermic reaction.

### Second Embodiment

A substrate processing apparatus 100 in a second embodiment supplies a hydrogen peroxide solution to a first supply pipe 25 from two or more selection branch pipes that are selected from among a plurality of branch pipes 26a to 26d. Further, the substrate processing apparatus 100 in the second embodiment does not supply a hydrogen peroxide solution to the first supply pipe 25 from one or more selection branch pipes that are not selected from among the plurality of branch pipes 26a to 26d. As described above, the respective distances between the respective branch pipes 26a to 26d and a discharge port OH are different. Therefore, when two or more selection branch pipes that are selected from among the branch pipes 26a to 26d are different, the concentrations of Caro's acid in SPM liquids discharged from the discharge port OH are different. The substrate processing apparatus 100 in the second embodiment adjusts the concentration of Caro's acid in the SPM liquid discharged from the discharge port OH.

The configuration of the substrate processing apparatus 100 in the second embodiment is basically the same as the configuration of the substrate processing apparatus 100 in the first embodiment. Differences of the substrate processing apparatus 100 in the second embodiment from the substrate processing apparatus 100 in the first embodiment will be described below.

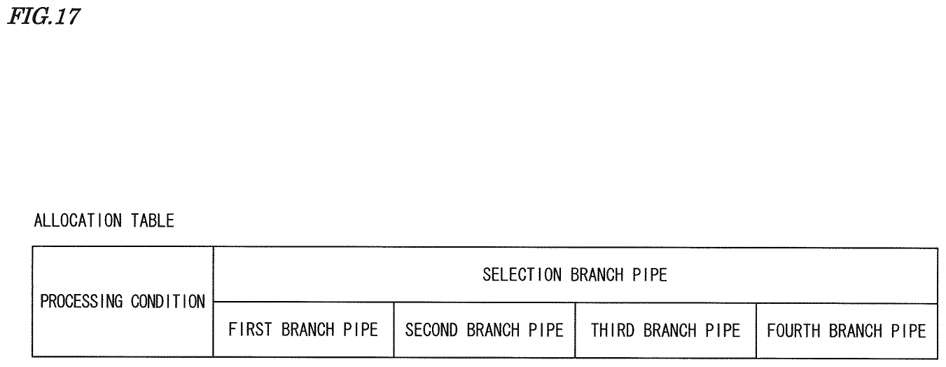

FIG. 16 is a block diagram showing one example of the functional configuration of a controller in the second embodiment. With reference to FIG. 16, the functions of the controller 50 shown in FIG. 17 are different from those of the controller 50 shown in FIG. 7 in that the open-close controller 503 is changed to an open-close controller 503A, and a processing condition acquirer 601 and a selector 603 are added. The other functions are the same as those shown in FIG. 7. A description thereof will therefore not be repeated.

The processing condition acquirer 601 accepts a processing condition for a process for a substrate W. In a case in which the substrate W is processed, the required concentration of Caro's acid in an SPM liquid may vary depending on the process contents. The processing condition acquirer 601 acquires a processing condition for the process for the substrate W, with the condition being received from outside by an input-output I/F 517. The processing condition acquirer 601 outputs the acquired processing condition to the selector 603. The substrate processing apparatus 100 executes a process of stripping a resist film. The processing condition includes the information in regard to the resist film formed on the substrate W. The information in regard to the resist film includes the type, thickness and the like of the resist film.

With reference to an allocation table stored in a storage device 514, the selector 603 selects two or more selection branch pipes from among the plurality of branch pipes 26a to 26d. The allocation table associates a processing condition with two or more selection branch pipes.

FIG. 17 is a diagram showing one example of the format of the allocation table. With reference to FIG. 17, the allocation table stores one or more allocation records. The allocation record associates a processing condition with a branch pipe to be used among the branch pipes 26a to 26d. The allocation record includes a field for a processing condition and a field for a selection branch pipe. The field for the selection branch pipe includes four fields of a first branch pipe to a fourth branch pipe. The field for the first branch pipe corresponds to the branch pipe 26a. The field for the second branch pipe corresponds to the branch pipe 26b. The field for the third branch pipe corresponds to the branch pipe 26c. The field for the fourth branch pipe corresponds to the branch pipe 26d.

A processing condition is set in the field for the processing condition of the allocation record. In the field for the selection branch pipe of the allocation record, a mark indicating which one of the branch pipes 26a to 26d is used is set. Specifically, the mark indicating the use of the branch pipe 26a is set in the field for the first branch pipe of the allocation record. The mark indicating the use of the branch pipe 26b is set in the field for the second branch pipe of the allocation record. The mark indicating the use of the branch pipe 26c is set in the field for the third branch pipe of the allocation record. The mark indicating the use of the branch pipe 26d is set in the field for the fourth branch pipe of the allocation record.

In the second embodiment, in each of the plurality of allocation records included in the allocation table, the mark indicating the use of the branch pipe 26d is set in the field for the fourth branch pipe of the allocation record. Further, in each of the plurality of allocation records, the mark indicating the use of the corresponding branch pipe is set in one or more fields for the first branch pipe to the third branch pipe of the allocation record. Therefore, each of the plurality of allocation records defines the use of two or more selection branch pipes.

Returning to FIG. 16, in response to receiving a processing condition from the processing condition acquirer 601, the selector 603 selects one allocation record corresponding to the processing condition with reference to the allocation table. The selector 603 specifies two or more selection branch pipes defined in the fields for the selection branch pipes of the selected allocation record. The selector 603 outputs identification information for identifying each of the two or more specified selection branch pipes to the open-close controller 503A.

In a case in which the mark indicating the use of the branch pipe 26a is set in the field for the first branch pipe of the allocation record, the selector 603 specifies the branch pipe 26a as a selection branch pipe. However, in a case in which the mark indicating the use of the branch pipe 26a is not set in the field for the first branch pipe, the selector 603 does not specify the branch pipe 26a as a selection branch pipe. In a case in which the mark indicating the use of the branch pipe 26b is set in the field for the second branch pipe of the allocation record, the selector 603 specifies the branch pipe 26b as a selection branch pipe. However, in a case in which the mark indicating the use of the branch pipe 26b is not set in the field for the second branch pipe, the selector 603 does not specify the branch pipe 26b as a selection branch pipe. In a case in which the mark indicating the use of the branch pipe 26c is set in the field for the third branch pipe of the allocation record, the selector 603 specifies the branch pipe 26c as a selection branch pipe. However, in a case in which the mark indicating the use of the branch pipe 26c is not set in the field for the third branch pipe, the selector 603 does not specify the branch pipe 26c as a selection branch pipe. In a case in which the mark indicating the use of the branch pipe 26d is set in the field for the fourth branch pipe of the allocation record, the selector 603 specifies the branch pipe 26d as a selection branch pipe. However, in a case in which the mark indicating the use of the branch pipe 26d is not set in the field for the fourth branch pipe, the selector 603 does not specify the branch pipe 26d as a selection branch pipe.

The open-close controller 503A controls a main open-close valve V, a first open-close valve Va, a second open-close valve Vb, a third open-close valve Vc and a fourth open-close valve Vd. The open-close controller 503A switches the main open-close valve V between an open state and a close state. When the close state is switched to the open state, a sulfuric acid is supplied to the first supply pipe 25 with a predetermined pressure. The open-close controller 503A switches each of the first open-close valve Va, the second open-close valve Vb, the third open-close valve Vc and the fourth open-close valve Vd to either one of the open state and the close state. When the first open-close valve Va is switched from the close state to the open state, a hydrogen peroxide solution is supplied to a first mixing position AA of the first supply pipe 25. When the second open-close valve Vb is switched from the close state to the open state, a hydrogen peroxide solution is supplied to a second mixing position BB of the first supply pipe 25. When the third open-close valve Vc is switched from the close state to the open state, a hydrogen peroxide solution is supplied to a third mixing position CC of the first supply pipe 25. When the fourth open-close valve Vd is switched from the close state to the open state, a hydrogen peroxide solution is supplied to a fourth mixing position DD of the discharge nozzle 21b.

The open-close controller 503A receives two or more identification information pieces from the selector 603. The open-close controller 503A specifies an open-close valve that is provided to correspond to a selection branch pipe specified by an identification information piece. In a case in which the identification information piece specifies the branch pipe 26a, the first open-close valve Va provided in the branch pipe 26a is specified. In a case in which the identification information piece specifies the branch pipe 26b, the second open-close valve Vb provided in the branch pipe 26b is specified. In a case in which the identification information piece specifies the branch pipe 26c, the third open-close valve Vc provided in the branch pipe 26c is specified. In a case in which the identification information piece specifies the branch pipe 26d, the fourth open-close valve Vd provided in the branch pipe 26d is specified.

Hereinafter, an open-close valve provided to correspond to a selection branch pipe is referred to as a selection valve. Based on two or more identification information pieces received from the selector 603, the open-close controller 503A switches two or more selection valves specified from among the first to fourth open-close valves Va to Vd to the open state and switches an open-close valve other than the two or more selection valves to the close state. In a case in which all of the first to fourth open-close valves Va to Vd are specified, the open-close controller 503A switches all of the first to fourth open-close valves Va to Vd to the open state. Therefore, a hydrogen peroxide solution is supplied to the first supply pipe 25 at two or more of the first mixing position AA to the fourth mixing position DD.

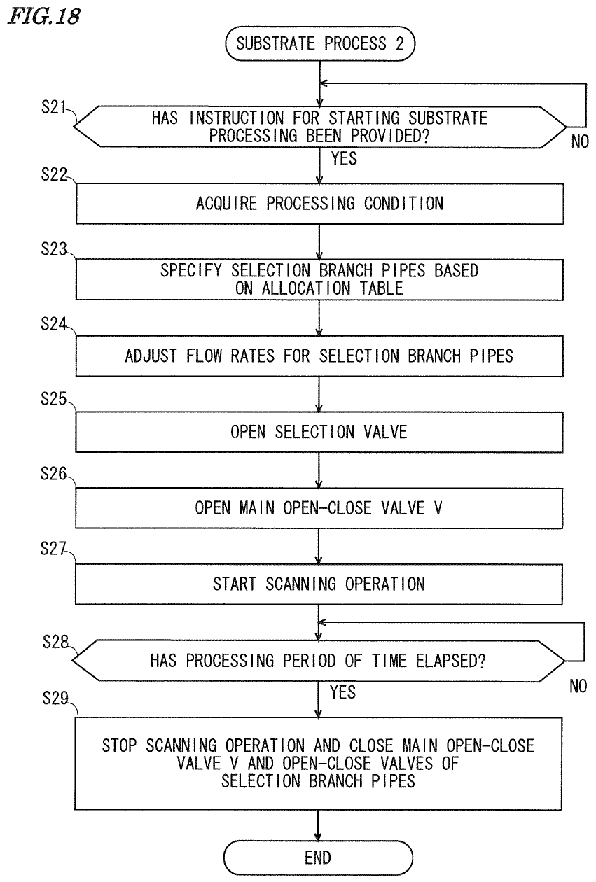

FIG. 18 is a flowchart for explaining one example of a flow of a substrate process in the second embodiment. With reference to FIG. 18, the CPU 511 included in the controller 50 determines whether the substrate process has started (step S21). A point in time at which the substrate W rotated by a spin chuck 10 reaches a predetermined number of rotations is detected as a start point in time of the substrate process. The CPU 511 moves the discharge nozzle 21b from the waiting position to a position above the substrate. The CPU 511 waits until the start of the substrate process is detected. When the start of the substrate process is detected, the process proceeds to the step S22.

In the step S22, a processing condition for the process for the substrate W is acquired, and the process proceeds to the step S23. A processing condition received from the outside is acquired. In the step S23, selection branch pipes are specified based on the allocation table, and the process proceeds to the step S24. One allocation record corresponding to the processing condition acquired in the step S22 is selected from among a plurality of allocation records included in the allocation table stored in the storage device 514. Then, two or more selection branch pipes defined to be used according to the selected allocation record are specified.

In the step S24, the flow rates respectively corresponding to the first supply pipe 25 and the two or more selection branch pipes are adjusted, and the process proceeds to step S25. A main flow rate, a first flow rate, a second flow rate, a third flow rate and a fourth flow rate stored in the storage device 514 are read. The main flow rate is the flow rate of a sulfuric acid for the first supply pipe 25. The CPU 511 provides an electrical signal indicating the main flow rate to a main adjustment valve NV. The main adjustment valve NV is adjusted to have an opening (a degree of opening) that causes the flow rate of a sulfuric acid flowing from the first supply pipe 25 toward the discharge port OH to be the main flow rate. Thus, the main adjustment valve NV is adjusted to have an opening (a degree of opening) that causes the flow rate of a sulfuric acid flowing from the first supply pipe 25 toward the discharge port OH to be the main flow rate.

The first flow rate is the flow rate of a hydrogen peroxide solution for the branch pipe 26a. The CPU 511 provides an electrical signal indicating the first flow rate to a first adjustment valve NVa. The first adjustment valve NVa is adjusted to have an opening that causes the flow rate of a hydrogen peroxide solution flowing from the branch pipe 26a toward the first mixing position AA to be the first flow rate. The second flow rate is the flow rate of a hydrogen peroxide solution for the branch pipe 26b. The CPU 511 provides an electrical signal indicating the second flow rate to a second adjustment valve NVb. The second adjustment valve NVb is adjusted to have an opening that causes the flow rate of a hydrogen peroxide solution flowing from the branch pipe 26b toward the second mixing position BB to be the second flow rate.

The third flow rate is the flow rate of a hydrogen peroxide solution for the branch pipe 26c. The CPU 511 provides an electrical signal indicating the third flow rate to a third adjustment valve NVc. The third adjustment valve NVc is adjusted to have an opening that causes the flow rate of a hydrogen peroxide solution flowing from the branch pipe 26c toward the third mixing position CC to be the third flow rate. The fourth flow rate is the flow rate of a hydrogen peroxide solution for the branch pipe 26d. The CPU 511 provides an electrical signal indicating the fourth flow rate to a fourth adjustment valve NVd. Thus, the fourth adjustment valve NVd is adjusted to have an opening that causes the flow rate of a hydrogen peroxide solution flowing from the branch pipe 26d toward the fourth mixing position DD to be the fourth flow rate.

In the step S25, the selection valves among the first open-close valve Va, the second open-close valve Vb, the third open-close valve Vc and the fourth open-close valve Vd are opened at the same time. The selection valves correspond to the selection branch pipes specified in the step S23. The first open-close valve Va corresponds to the branch pipe 26a, the second open-close valve Vb corresponds to the branch pipe 26b, the third open-close valve Vc corresponds to the branch pipe 26c, and the fourth open-close valve Vd corresponds to the branch pipe 26d.

For example, in a case in which the branch pipe 26a and the branch pipe 26d are specified as selection branch pipes, the first open-close valve Va and the fourth open-close valve Vd are opened at the same time. In this case, a hydrogen peroxide solution is supplied from each of the first mixing position AA and the fourth mixing position DD of the first supply pipe 25. Further, in a case in which the branch pipe 26a, the branch pipe 26b and the branch pipe 26d are specified as selection branch pipes, for example, the first open-close valve Va, the second open-close valve Vb and the fourth open-close valve Vd are opened at the same time. In this case, a hydrogen peroxide solution is supplied from each of the first mixing position AA, the second mixing position BB and the fourth mixing position DD of the first supply pipe 25. Further, in a case in which the branch pipe 26a, the branch pipe 26b, the branch pipe 26c and the branch pipe 26d are all specified as selection branch pipes, for example, the first open-close valve Va, the second open-close valve Vb, the third open-close valve Vc and the fourth open-close valve Vd are opened at the same time. In this case, a hydrogen peroxide solution is supplied from each of the first mixing position AA, the second mixing position BB, the third mixing position CC and the fourth mixing position DD of the first supply pipe 25.

The process of the steps S26 to S29 is the same as the process of the steps S9 to S12 shown in FIG. 8. Therefore, the description will not be repeated here.

In the substrate processing apparatus 100 in the second embodiment, at least two of the four mixing positions AA, BB, CC, DD are selected, and a sulfuric acid and a hydrogen peroxide solution are sequentially mixed in the first supply pipe 25 at at least two mixing positions, with the mixing starting at the mixing position that is the farthest from the discharge port OH and finishing at the mixing position that is the closest from the discharge port OH. Therefore, it is possible to change the concentration of Caro's acid in an SPM liquid by changing a combination of at least two selected mixing positions.

Further, at least two mixing positions are selected based on a processing condition for the process for the substrate W. Therefore, it is possible to adjust the concentration of Caro's acid in the SPM liquid according to the processing condition.

### Third Embodiment

Similarly to the substrate processing apparatus 100 in the second embodiment, a substrate processing apparatus 100 in a third embodiment supplies a hydrogen peroxide solution to a first supply pipe 25 from two or more selection branch pipes that are selected from among a plurality of branch pipes 26a to 26d. Based on a processing result obtained when the substrate W is processed, the substrate processing apparatus 100 in the third embodiment changes two or more selection branch pipes to be selected from among the plurality of branch pipes 26a to 26d based on a processing result obtained when the substrate W is processed. The configuration of the substrate processing apparatus 100 in the third embodiment is basically the same as the configuration of the substrate processing apparatus 100 in the second embodiment. Differences of the substrate processing apparatus 100 in the third embodiment from the substrate processing apparatus 100 in the second embodiment will be described below.

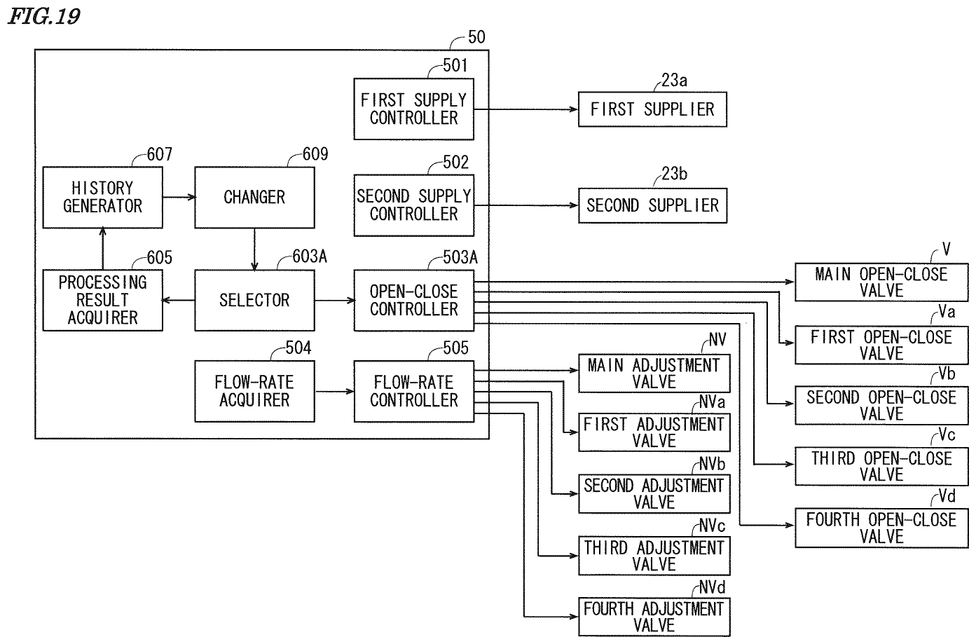

FIG. 19 is a block diagram showing one example of the functional configuration of a controller in the third embodiment. With reference to FIG. 19, the differences from the functions of the controller 50 shown in FIG. 16 are that the processing condition acquirer 601 is removed, the selector 603 is changed to a selector 603A, and the processing result acquirer 605, a history generator 607 and a changer 609 are added. The other functions are the same as those shown in FIG. 16. A description thereof will therefore not be repeated.

When the substrate processing apparatus 100 is started, the selector 603 selects two or more selection branch pipes that cause the concentration of Caro's acid to be the lowest from among the plurality of branch pipes 26a to 26d. The selector 603A outputs identification information for identifying each of the two or more selected selection branch pipes to an open-close controller 503A and the processing result acquirer 605. Here, the branch pipe 26a and the branch pipe 26d are selected, by way of example. In this case, the identification information for each of the branch pipe 26a and the branch pipe 26d is output to the processing result acquirer 605.

After the substrate processing apparatus 100 processes the substrate W, the processing result acquirer 605 acquires a processing result in regard to the process for the substrate W. The processing result acquirer 605 outputs the processing result to the history generator 607 together with the identification information received from the selector 603. The substrate processing apparatus 100 executes a process of stripping a resist film formed on the obverse surface of the substrate W. The processing result is an index for evaluating this process. Here, a stripping rate is used as an index, by way of example. The stripping rate is obtained when an image process is executed on an image obtained when a camera picks up an image of the substrate W.

The history generator 607 generates history information including the processing result received from the processing result acquirer 605. The history information associates the selection branch pipes among the branch pipes 26a to 26d with the processing result. The history generator 607 outputs the history information to the changer 609.

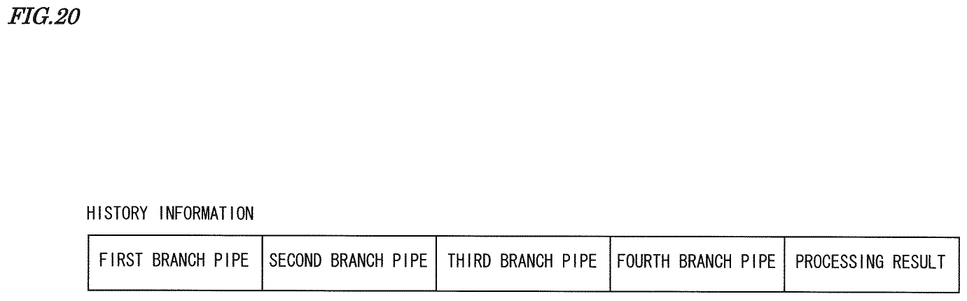

FIG. 20 is a diagram showing one example of the format of history information. With reference to FIG. 20, the history information includes four fields for first to fourth branch pipes and a field for a processing result. The field for the first branch pipe corresponds to the branch pipe 26a. The field for the second branch pipe corresponds to the branch pipe 26b. The field for the third branch pipe corresponds to the branch pipe 26c. The field for the fourth branch pipe corresponds to the branch pipe 26d.

In the field for the processing result of history information, the stripping rate which is a processing result received from the processing result acquirer 605 is set. A mark indicating a selection branch pipe is set in each of the four fields for the first branch pipe to the fourth branch pipe of an allocation record. Specifically, in a case in which the identification information received from the processing result acquirer 605 specifies the branch pipe 26a, the mark indicating that the branch pipe 26a is the selection branch pipe is set. In a case in which the identification information received from the processing result acquirer 605 specifies the branch pipe 26b, the mark indicating that the branch pipe 26b is the selection branch pipe is set. In a case in which the identification information received from the processing result acquirer 605 specifies the branch pipe 26c, the mark indicating that the branch pipe 26c is the selection branch pipe is set. In a case in which the identification information received from the processing result acquirer 605 specifies the branch pipe 26d, the mark indicating that the branch pipe 26d is the selection branch pipe is set.

Returning to FIG. 19, the changer 609 changes two or more selection branch pipes based on the history information. In a case in which the difference between a processing result included in the history information and a target value exceeds a predetermined range, the changer 609 changes two or more selection branch pipes. The changer 609 changes a set of two or more selection branch pipes such that the concentration of Caro's acid included in an SPM liquid increases. The closer a mixing position among first to fourth mixing positions AA, BB, CC, DD is to a discharge port OH, the higher the concentration of Caro's acid is likely to be. Therefore, the changer 609 changes the selection branch pipe that is the farthest from the discharge port OH among the current selection branch pipes to a selection branch pipe closer from the discharge port OH. The changer 609 outputs two or more identification information pieces for identifying new two or more selection branch pipes after the change to the selector 603A.

In response to receiving the two or more identification information pieces from the changer 609, the selector 603A selects the two or more selection branch pipes respectively specified by the two or more identification information pieces from among the plurality of branch pipes 26a to 26d. The selector 603A outputs the identification information pieces for respectively identifying the two or more selected selection branch pipes to the open-close controller 503A and the processing result acquirer 605.

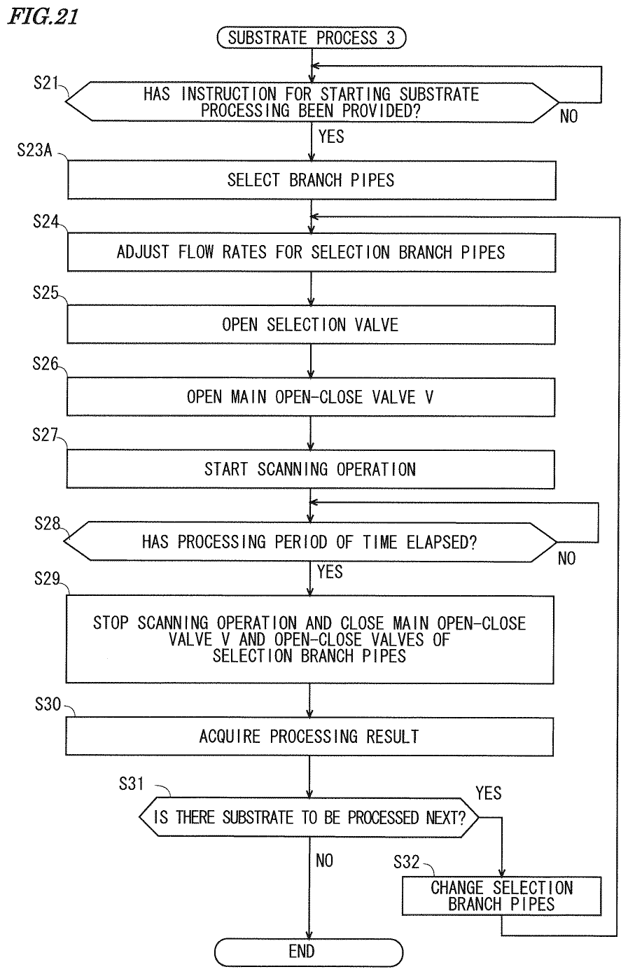

FIG. 21 is a flowchart for explaining one example of a flow of a substrate process in the third embodiment. With reference to FIG. 21, the differences from the substrate process in the second embodiment shown in FIG. 18 are that the step S22 is removed, the step S23 is changed to the step S23A, and the steps S30 to S32 are added. The other processes are the same as those shown in FIG. 18. A description thereof will therefore not be repeated here.

When it is determined in the step S21 that the substrate process has been started, the process proceeds to the step S23A. In the step S23A, two or more branch pipes are selected, and the process proceeds to the step S24. The two or more branch pipes selected in the step S23A are determined in advance. Here, the branch pipe 26a and the branch pipe 26d that causes the concentration of Caro's acid to be the lowest are selected.

When a scanning operation and the discharge of an SPM liquid are stopped in the step S29, the process proceeds to the step S30. In the step S30, a processing result is acquired, and the process proceeds to the step S31. The processing result is an index with which it is possible to evaluate a process, executed by the substrate processing apparatus 100, of stripping a resist film formed on the obverse surface of the substrate W. Here, a stripping rate is used as the index.

In the step S31, it is determined whether there is a substrate to be processed next. If there is a substrate to be processed, the process proceeds to the step S32. If not, the process ends. In the step S32, the selection branch pipes are changed based on the processing result, and the process returns to the step S24. The current two or more selection branch pipes are changed to new two or more selection branch pipes such that the concentration of Caro's acid s higher than that with the current two or more selection branch pipes. Therefore, in the period during which the next steps S24 to S30 are executed, a hydrogen peroxide solution is supplied from the new two or more selection branch pipes.

The substrate processing apparatus 100 in the third preferred embodiment selects at least two of the four mixing positions AA, BB, CC, DD, acquires a processing result obtained when the substrate W is processed using the selected at least two mixing positions, and changes a set of the at least two mixing positions selected for the substrate W to be processed next based on the processing result. Therefore, the processing result obtained when the substrate W is processed is fed back in regard to the process for the substrate W to be processed next. Therefore, a set of at least two mixing positions can be suitably defined in a period during which a plurality of substrates W are sequentially processed.

### Fourth Embodiment

A substrate processing apparatus 100 in a fourth embodiment generates the allocation table used in the substrate processing apparatus 100 in the second embodiment based on history information. The configuration of the substrate processing apparatus 100 in the fourth embodiment is basically the same as the configuration of the substrate processing apparatus 100 in the second embodiment. Differences of the substrate processing apparatus 100 in the fourth embodiment from the substrate processing apparatus 100 in the second embodiment will be described below.

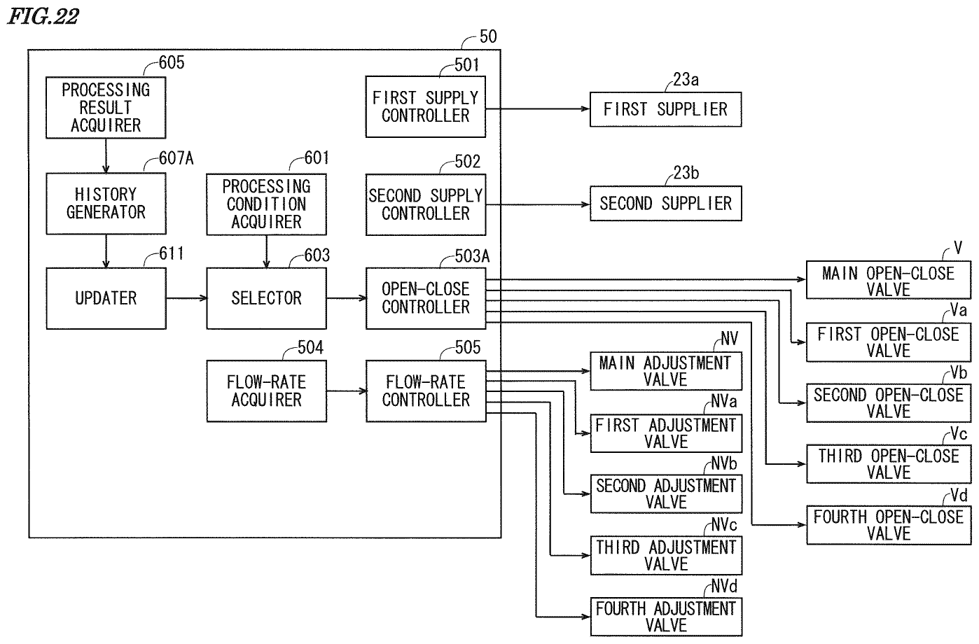

FIG. 22 is a block diagram showing one example of the functional configuration of a controller in the fourth embodiment. With reference to FIG. 22, the differences from the functions of the controller 50 shown in FIG. 16 are that a processing result acquirer 605, a history generator 607A and an updater 611 are added. The other functions are the same as those shown in FIG. 16. A description thereof will therefore not be repeated.

In the fourth embodiment, four branch pipes 26a to 26d are used. Two or more selection branch pipes include the branch pipe 26d, and one or more branch pipes out of the other three branch pipes 26b to 26d. Therefore, the number of combinations of two or more selection branch pipes are seven in total. The combinations include three combinations each of which includes two selection branch pipes, three combinations each of which includes three selection branch pipes, and one combination including four selection branch pipes.

After the substrate processing apparatus 100 processes a substrate W, the processing result acquirer 605 acquires a processing result in regard to the process for the substrate W. The processing result acquirer 605 outputs the processing result to the history generator 607A. The substrate processing apparatus 100 executes a process of stripping a resist film formed on the obverse surface of the substrate W. The processing result is an index for evaluating this process. Here, a stripping rate is used as an index, by way of example. The stripping rate is obtained when an image process is executed on an image obtained when a camera picks up an image of the substrate W.

The history generator 607A generates history information including the processing result received from the processing result acquirer 605. The history information associates a processing condition, a selection branch pipe out of the branch pipes 26a to 26d and the processing result with one another. The history generator 607A stores the history information in the storage device 514.

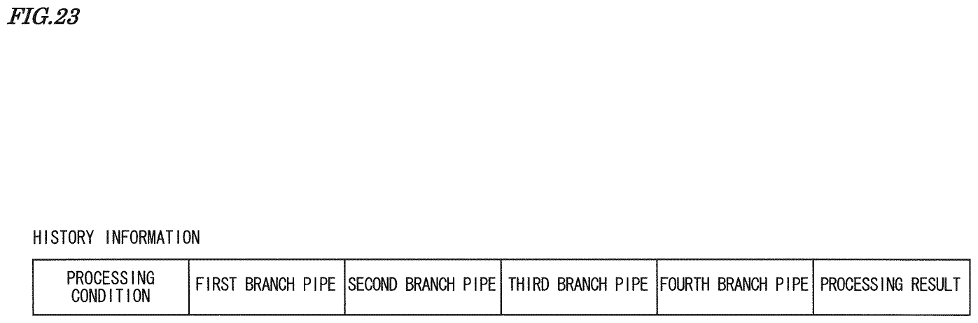

FIG. 23 is a diagram showing one example of the format of history information in the fourth embodiment. With reference to FIG. 23, a field for a processing condition is added to the history information shown in FIG. 20. In the field for the processing condition of the history information, a processing condition is set.

Returning to FIG. 22, the updater 611 updates an allocation table after the history information is generated by the history generator 607A in regard to each of seven combinations each of which includes two or more selection branch pipes. For example, the updater 611 reads out a plurality of history information pieces stored in the storage device 514 by the history generator 607A, and statistically processes the plurality of history information pieces to determine an optimum value for two or more selection branch pipes. Specifically, in regard to the same processing condition, the updater 611 determines a set of two or more selection branch pipes having an optimum value as a result of a statistical process of the processing result as an optimum value.

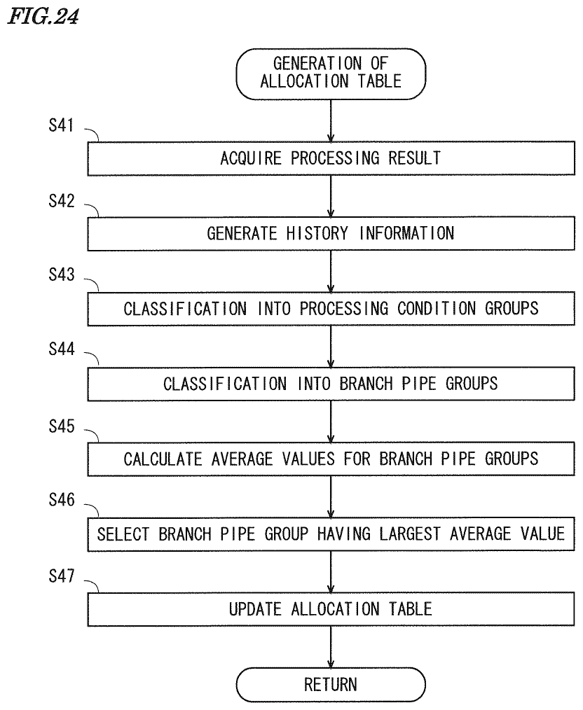

FIG. 24 is a flowchart showing one example of a flow of an allocation table generation process. With reference to FIG. 24, the CPU 511 included in the controller 50 acquires a processing result (step 41), and the process proceeds to the step S42.

In the step S42, history information is generated based on the processing result, and the process proceeds to the step S43. The history information in the format shown in FIG. 23 is generated. The history information includes a processing condition, usability of each of the first to fourth branch pipes 26a to 26d and a processing result. The history information is stored in the storage device 514.

In the step S43, history information pieces are classified into processing condition groups, and the process proceeds to the step S44. A processing condition group includes history information pieces having the same processing condition. Therefore, the number of processing condition groups is the same as the number of processing conditions. The history information pieces are classified into processing condition groups. Each processing condition group includes history information pieces having the same processing condition. In the step S44, the history information pieces are classified into branch pipe groups, and the process proceeds to the step S45. In each branch pipe group, history information pieces having the same branch pipe to be used (selection branch pipe) are included. Therefore, the number of branch pipe groups is the same as the number of sets (seven in the present example) each of which includes two or more selection branch pipes. A history information piece is classified into one branch pipe group for a set of two or more selection branch pipe that are the same set of selection branch pipes specified in the fields for the first to fourth branch pipes included in the history information piece.

In the step S45, the average values for the branch pipe groups are calculated, and the process proceeds to the step S46. The average values in regard to the processing results are calculated in regard to the plurality of history information pieces included in the branch pipe group into which the history information pieces are classified.

In the step S46, an allocation table is updated, and the process ends. The branch pipe group having the largest average value is selected from among a plurality of branch pipe groups having the same processing condition as the processing condition included in a plurality of history information pieces. Then, the allocation record including the same processing condition as the processing condition included in a plurality of history information pieces is specified from among a plurality of allocation records included in the allocation table. Further, the fields for the selection branch pipes of the specified allocation record are updated with the values indicating that two or more selection branch pipes corresponding to the branch pipe group having the highest average value are used.

The substrate processing apparatus 100 in the fourth embodiment acquires a processing result obtained when the substrate W is processed, generates history information in which at least two mixing positions and the processing result are associated with each other, and determines an optimum value in regard to a set of at least two mixing positions for a processing condition based on the history information. Therefore, it is possible to determine a set of at least two mixing positions for a processing condition without measuring a concentration of Caro's acid in an SPM liquid. Further, because the allocation table is generated by a process for the substrate W, the allocation table suitable for the substrate processing apparatus 100 can be generated.

### Correspondences Between Constituent Elements in Claims and Parts in Preferred Embodiments

The discharge port OH is an example of a discharge port, the first supply pipe 25 is an example of a first supply path, the mixing positions AA to DD are examples of a mixing position, the branch pipes 26a to 26d are an example of a plurality of second supply paths, the first supplier 23a is an example of a first supplier, the second supplier 23b is an example of a second supplier, and Caro's acid, water, a sulfuric acid and a hydrogen peroxide solution are examples of liquid. The controller 50 is an example of a controller, the first to fourth open-close valves Va to Vd are an example of a plurality of first switchers, the connection path 26Aa is an example of a connection path, the switching valve Vv is an example of a second switcher, and the stirrer 27 is an example of a stirrer. The controller 50 is an example of a controller, the processing condition acquirer 601 is an example of a processing condition acquirer, the selectors 603, 603A are examples of a selector, the processing result acquirers 605, 605A are examples of a processing result acquirer, the history generator 607 is an example of a history generator, the changer 609 is an example of a changer, and the updater 611 is an example of a determiner.

### Overview of Embodiments

(Item 1) A substrate processing apparatus according to one aspect that generates a third processing liquid using a first processing liquid and a second processing liquid and processes a substrate using the third processing liquid, includes a discharge port, a first supply path connected to the discharge port, a plurality of second supply paths respectively connected to the first supply path at a plurality of mixing positions having different flow-path lengths to the discharge port, a first supplier that supplies the first processing liquid to the first supply path, and a second supplier that supplies the second processing liquid to the first supply path through the plurality of second supply paths, wherein at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

In the substrate processing apparatus according to item 1, at each of the plurality of mixing positions, the first processing liquid and the second processing liquid are mixed. The first processing liquid and the second processing liquid undergo the first chemical reaction to generate the third processing liquid. In a case in which the first chemical reaction is an exothermic reaction, the first chemical reaction may be promoted at a temperature equal to or higher than a predetermined temperature, and the second chemical reaction in which the second processing liquid is broken down into two or more substances may progress at a temperature equal to or higher than a temperature lower than the predetermined temperature. In this case, the first chemical reaction and the second chemical reaction progress at the same time in regard to each mixing of the first processing liquid and the second processing liquid. Therefore, at a temperature equal to or higher than the predetermined temperature, the first chemical reaction progresses and the second chemical reaction progresses. Because the second processing liquid is reduced due to the progress of the second chemical reaction, the first chemical reaction is prevented. The liquid in the first supply path and the second processing liquid are sequentially mixed at the plurality of mixing positions of the first supply path, the mixing starting at the mixing position that is the farthest from the discharge port and finishing at the mixing position that is the closest from the discharge port. Thus, the ratio of an amount of the second processing liquid with respect to an amount of the first processing liquid present in the first supply path at each of the plurality of mixing positions can be set equal to or larger than a predetermined ratio, and the first chemical reaction can be continued. Therefore, it is possible to reduce the usage amount of the second processing liquid while causing the first chemical reaction to effectively progress. As a result, it is possible to provide the substrate processing apparatus capable of reducing the consumption of the chemical liquid to be used.

(Item 2) The substrate processing apparatus according to item 1, may further include a controller that controls the first supplier and the second supplier, wherein the controller may control the second supplier to supply the second processing liquid to the plurality of mixing positions in the first supply path, and then may control the first supplier to supply the first processing liquid to the first supply path.

With the substrate processing apparatus according to item 2, the first processing liquid is supplied after the second processing liquid is supplied at each of the plurality of mixing positions in the first supply path. In this case, with the simple control of the first supplier and the second supplier, the third processing liquid can be generated.

(Item 3) The substrate processing apparatus according to item 1, may further include a controller that controls the first supplier and the second supplier, wherein the controller may control the first supplier and the second supplier, and may supply the second processing liquid to the plurality of mixing positions with the first processing liquid being supplied to the plurality of mixing positions.

With the substrate processing apparatus according to item 3, with the first processing liquid supplied to each of the plurality of mixing positions in the first supply path, the second processing liquid is supplied. Therefore, the second processing liquid is sequentially mixed with the liquid in the first supply path. Therefore, it is possible to reduce the usage amount of the second processing liquid while causing the first chemical reaction to effectively progress.

(Item 4) The substrate processing apparatus according to item 1, may further include a plurality of first switchers that are respectively arranged in the plurality of second supply paths and switch between supply and stop of supply in regard to supply of the second processing liquid from the second supply paths to the first supply path, wherein the larger a flow-path length between the mixing position and the discharge port is, the smaller a flow-path length from the first switcher in each of the plurality of second supply path to the mixing position may be, with the mixing position being a position at which each of the plurality of second supply paths is connected to the first supply path.

With the substrate processing apparatus according to item 4, in a case in which the plurality of first switchers are switched, at the same time, from the stop state to the state in which the second processing liquid is supplied, the second processing liquid is sequentially supplied at the mixing positions, the supply starting at the mixing position having the large flow-path length from the discharge port and finishing at the mixing position having the small flow-path length from the discharge port. Therefore, the periods of time required until the second processing liquid reaches the respective mixing positions can be made different. In a case in which a point in time at which the state of the first switcher is switched is determined according to the point in time at which the first processing liquid is supplied, the second processing liquid can reach each of the plurality of mixing points before the first processing liquid reaches. As a result, it is possible to efficiently mix the first processing liquid and the second processing liquid and suppress the consumption of the first processing liquid and the second processing liquid.

(Item 5) The substrate processing apparatus according to item 1, may further include a single connection path provided between the second supplier and the plurality of second supply paths, and a second switcher that is provided in the connection path and switches between supply and stop of supply in regard to supply of the second processing liquid from the second supplier to the plurality of second supply paths, wherein the larger a flow-path length between the mixing position and the discharge port is, the smaller a flow-path length between each of the plurality of mixing positions and the second switcher may be.

With the substrate processing apparatus according to item 5, the second processing liquid is sequentially supplied at mixing positions, with the mixing starting at the mixing position having a large flow-path length from the discharge port and finishing at the mixing position having a small flow-path length from the discharge port. Therefore, the periods of time required until the second processing liquid reaches the respective mixing positions can be made different. In a case in which a point in time at which the state of the switcher is switched is determined according to the point in time at which the first processing liquid is supplied, the second processing liquid can reach each of the plurality of mixing points at the point in time at which the first processing liquid reaches. As a result, it is possible to suppress the consumption of the first processing liquid and the second processing liquid.

(Item 6) The substrate processing apparatus according to any one of items 1 to 5, wherein the second supplier may cause a flow rate of the second processing liquid flowing through a final supply path among the plurality of second supply paths to be larger than a flow rate of the second processing liquid flowing through another one or more out of the plurality of second supply paths, with the final supply path being connected to the first supply path at the mixing position having a smallest flow-path length from the discharge port.

With the substrate processing apparatus according to item 6, the second processing liquid having a large flow rate is supplied to the first supply path at the position that is the closest to the discharge port. Thus, because the amount of the second processing liquid mixed with the first processing liquid is at the maximum when the first processing liquid has the highest temperature, the third processing liquid can be efficiently generated.

(Item 7) The substrate processing apparatus according to any one of items 1 to 6, may further include a stirrer that is provided in the first supply path and stirs liquid flowing through the first supply path.

In the substrate processing apparatus according to the item 7, the first processing liquid and the second processing liquid mixed in the first supply path are stirred by the stirrer. This promotes mixing of the first processing liquid and the second processing liquid, so that an amount of the first processing liquid subject to the first chemical reaction can be increased.

(Item 8) The substrate processing apparatus according to item 7, wherein the stirrer may be provided at a position such that a flow-path length from the stirrer to a first mixing position is equal to or larger than a flow-path length between the first mixing position and a second mixing position having a second largest flow-path length from the discharge port, with the first mixing position having a largest flow-path length from the discharge port among the plurality of mixing positions.

In the substrate processing apparatus according to item 8, the first processing liquid and the second processing liquid can be stirred before gas is generated in the first supply path. This can promote the first chemical reaction.

(Item 9) The substrate processing apparatus according to any one of items 1 to 8, wherein one of the first processing liquid and the second processing liquid may be a sulfuric acid, and another one of the first processing liquid and the second processing liquid may be a hydrogen peroxide solution.

With the substrate processing apparatus according to item 9, in the first chemical process, H₂SO₄+H₂O₂→H₂SO₅+H₂O in the first chemical progress, and 2H₂O₂→2H₂O+O₂ in the second chemical reaction. Therefore, it is possible to efficiently generate Caro's acid included in the SPM liquid.

(Item 10) The substrate processing apparatus according to item 9, wherein the first processing liquid may be a sulfuric acid, and the second processing liquid may be a hydrogen peroxide solution.

With the substrate processing apparatus according to item 10, the second processing liquid is supplied to the first supply path in multiple stages. In the first chemical reaction, H₂SO₄+H₂O₂→H₂SO₅+H₂O. In the second chemical reaction, 2H₂O₂→2H₂O+O₂. Therefore, it is possible to efficiently generate Caro's acid included in the SPM liquid and reduce the consumption of a hydrogen peroxide solution.

(Item 11) The substrate processing apparatus according to any one of items 1 to 10, further includes a controller that controls opening and closing of each of the plurality of second supply paths, wherein there is at least three mixing positions in regard to the plurality of mixing positions, the controller includes a selector that selects at least two out of the at least three mixing positions, and the second supplier is controlled such that, liquid in the first supply path is sequentially mixed with the second processing liquid at the at least two selected mixing positions, with mixing starting at the mixing position that is the farthest from the discharge port and finishing at the mixing position that is the closest from the discharge port.

With the substrate processing apparatus according to item 11, at least two out of at least three mixing positions are selected. Therefore, the liquid in the first supply path is sequentially mixed with the second processing liquid at at least two mixing positions, with the mixing starting at the mixing position that is the farthest from the discharge port and finishing at the mixing position that is the closest from the discharge port. Therefore, it is possible to change the concentration of the third processing liquid by changing the combination of at least two mixing positions.

(Item 12) The substrate processing apparatus according to item 11, wherein the controller further includes a processing condition acquirer that acquires a processing condition in regard to a process for the substrate, and the selector selects the at least two mixing positions based on the processing condition.

With the substrate processing apparatus according to item 12, at least two mixing positions are selected based on the processing condition for processing the substrate. Therefore, the concentration of a third processing liquid can be adjusted according to the processing condition.

(Item 13) The substrate processing apparatus according to item 12, wherein the controller includes a processing result acquirer that acquires a processing result in regard to a process for the substrate, a history generator that generates history information in which the at least two mixing positions selected by the selector are associated with the processing result, and a determiner that determines an optimum value in regard to a set of the at least two mixing positions for the processing condition based on the generated history information.

With the substrate processing apparatus according to item 13, a processing result of a substrate process is acquired, history information in which at least two mixing positions are associated with the processing result is generated, and an optimum value for a set of at least two mixing positions in regard to a processing condition is determined based on the history information. Based on the processing result, a set of at least two mixing positions in regard to a processing condition is determined. Therefore, it is possible to determine a set of at least two mixing positions in regard to the processing condition without measuring a concentration of a third processing liquid.

(Item 14) The substrate processing apparatus according to any one of items 1 to 10, may further include a controller that controls opening and closing of each of the plurality of second supply paths, wherein there may be at least three mixing positions in regard to the plurality of mixing positions, the controller may include a selector that selects at least two out of the at least three mixing positions, a processing result acquirer that acquires a processing result in regard to a process for the substrate using the at least two mixing positions selected by the selector, and a changer that changes a set of the at least two mixing positions selected by the selector based on the processing result.

According to this aspect, a processing result of a substrate process in which at least two mixing positions out of the at least three mixing positions are used is acquired, and a set of at least two mixing positions is changed based on the processing result. Because the processing result is fed back, a set of at least two mixing positions can be appropriately defined.

(Item 15) A substrate processing method according to another aspect of generating a third processing liquid using a first processing liquid and a second processing liquid, wherein the substrate processing method is executed by a substrate processing apparatus that processes a substrate using the third processing liquid, the substrate processing apparatus includes a discharge port, a first supply path connected to the discharge port, a plurality of second supply paths respectively connected to the first supply path at a plurality of mixing positions having different flow-path lengths to the discharge port, and the substrate processing method includes supplying the first processing liquid to the first supply path, and supplying the second processing liquid to the first supply path through the plurality of second supply paths, and at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

With the substrate processing method according to item 11, the liquid in the first supply path is sequentially mixed with the second processing liquid at the plurality of mixing positions of the first supply path, with the mixing starting at the mixing position that is the farthest from the discharge port and finishing at the mixing position that is the closest from the discharge port. Therefore, the ratio of an amount of the second processing liquid with respect to an amount of the first processing liquid present in the first supply path at each of the plurality of mixing positions can be equal to or larger than a predetermined ratio, and the first chemical reaction can be continued. Therefore, it is possible to reduce the usage amount of the second processing liquid while causing the first chemical reaction to effectively progress. As a result, it is possible to provide the substrate processing apparatus capable of reducing the consumption of the chemical liquid to be used.

(Item 16) A non-transitory computer readable recording medium storing a substrate processing program according to another aspect executed by a computer that controls a substrate processing apparatus, with the substrate processing apparatus generating a third processing liquid using a first processing liquid and a second processing liquid and processing a substrate using the third processing liquid, wherein the substrate processing apparatus includes a discharge port for discharging the third processing liquid, a first supply path connected to the discharge port, and a plurality of second supply paths respectively connected to the first supply path at a plurality of mixing positions having different flow-path lengths to the discharge port, the substrate processing program causes the computer to execute a step of supplying the first processing liquid to the first supply path, and a step of supplying the second processing liquid to the first supply path through the plurality of second supply paths, and at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

With the non-transitory computer-readable medium storing the substrate processing program according to item 12, the liquid in the first supply path is sequentially mixed with the second processing liquid at a plurality of mixing positions of the first supply path, with the mixing starting at the mixing position that is the farthest from the discharge port and finishing at the mixing position that is the closest from the discharge port. Therefore, the ratio of an amount of the second processing liquid with respect to an amount of the first processing liquid present in the first supply path at each of the plurality of mixing positions can be equal to or larger than a predetermined ratio, and the first chemical reaction can be continued. Therefore, it is possible to reduce the usage amount of the second processing liquid while causing the first chemical reaction to effectively progress. As a result, it is possible to provide the substrate processing apparatus capable of reducing the consumption of the chemical liquid to be used.

While preferred embodiments of the present disclosure have been described above, it is to be understood that variations and modifications will be apparent to those skilled in the art without departing the scope and spirit of the present disclosure. The scope of the present disclosure, therefore, is to be determined solely by the following claims.

I/We claim:

1. A substrate processing apparatus that generates a third processing liquid using a first processing liquid and a second processing liquid and processes a substrate using the third processing liquid, comprising:
a discharge port;
a first supply path connected to the discharge port;
a plurality of second supply paths respectively connected to the first supply path at a plurality of mixing positions having different flow-path lengths to the discharge port;
a first supplier that supplies the first processing liquid to the first supply path; and
a second supplier that supplies the second processing liquid to the first supply path through the plurality of second supply paths, wherein
at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

2. The substrate processing apparatus according to claim 1, further comprising a controller that controls the first supplier and the second supplier, wherein
the controller controls the second supplier to supply the second processing liquid to the plurality of mixing positions in the first supply path, and then controls the first supplier to supply the first processing liquid to the first supply path.

3. The substrate processing apparatus according to claim 1, further comprising a controller that controls the first supplier and the second supplier, wherein
the controller controls the first supplier and the second supplier, and supplies the second processing liquid to the plurality of mixing positions with the first processing liquid being supplied to the plurality of mixing positions.

4. The substrate processing apparatus according to claim 1, further comprising a plurality of first switchers that are respectively arranged in the plurality of second supply paths and switch between supply and stop of supply in regard to supply of the second processing liquid from the second supply paths to the first supply path, wherein
the larger a flow-path length between the mixing position and the discharge port, the smaller a flow-path length from the first switcher in each of the plurality of second supply path to the mixing position, with the mixing position being a position at which each of the plurality of second supply paths is connected to the first supply path.

5. The substrate processing apparatus according to claim 1, further comprising:
a single connection path provided between the second supplier and the plurality of second supply paths; and
a second switcher that is provided in the connection path and switches between supply and stop of supply in regard to supply of the second processing liquid from the second supplier to the plurality of second supply paths, wherein
the larger a flow-path length between the mixing position and the discharge port, the smaller a flow-path length between each of the plurality of mixing positions and the second switcher.

6. The substrate processing apparatus according to claim 1, wherein
the second supplier causes a flow rate of the second processing liquid flowing through a final supply path among the plurality of second supply paths to be larger than a flow rate of the second processing liquid flowing through another one or more out of the plurality of second supply paths, with the final supply path being connected to the first supply path at the mixing position having a smallest flow-path length from the discharge port.

7. The substrate processing apparatus according to claim 1, further comprising a stirrer that is provided in the first supply path and stirs liquid flowing through the first supply path.

8. The substrate processing apparatus according to claim 7, wherein
the stirrer is provided at a position such that a flow-path length from the stirrer to a first mixing position is equal to or larger than a flow-path length between the first mixing position and a second mixing position having a second largest flow-path length from the discharge port, with the first mixing position having a largest flow-path length from the discharge port among the plurality of mixing positions.

9. The substrate processing apparatus according to claim 1, wherein
one of the first processing liquid and the second processing liquid is a sulfuric acid, and another one of the first processing liquid and the second processing liquid is a hydrogen peroxide solution.

10. The substrate processing apparatus according to claim 9, wherein
the first processing liquid is a sulfuric acid, and the second processing liquid is a hydrogen peroxide solution.

11. The substrate processing apparatus according to claim 1, further comprising a controller that controls opening and closing of each of the plurality of second supply paths, wherein
there are at least three mixing positions in regard to the plurality of mixing positions,
the controller includes a selector that selects at least two out of the at least three mixing positions, and
the second supplier is controlled such that, liquid in the first supply path is sequentially mixed with the second processing liquid at the at least two selected mixing positions, with mixing starting at the mixing position that is the farthest from the discharge port and finishing at the mixing position that is the closest from the discharge port.

12. The substrate processing apparatus according to claim 11, wherein
the controller further includes a processing condition acquirer that acquires a processing condition in regard to a process for the substrate, and
the selector selects the at least two mixing positions based on the processing condition.

13. The substrate processing apparatus according to claim 12, wherein
the controller includes a processing result acquirer that acquires a processing result in regard to a process for the substrate,
a history generator that generates history information in which the at least two mixing positions selected by the selector are associated with the processing result, and
a determiner that determines an optimum value in regard to a set of the at least two mixing positions for the processing condition based on the generated history information.

14. The substrate processing apparatus according to claim 1, further comprising a controller that controls opening and closing of each of the plurality of second supply paths, wherein
there are at least three mixing positions in regard to the plurality of mixing positions,
the controller includes a selector that selects at least two out of the at least three mixing positions,
a processing result acquirer that acquires a processing result in regard to a process for the substrate using the at least two mixing positions selected by the selector, and
a changer that changes a set of the at least two mixing positions selected by the selector based on the processing result.

15. A substrate processing method of generating a third processing liquid using a first processing liquid and a second processing liquid, the substrate processing method being executed by a substrate processing apparatus that processes a substrate using the third processing liquid, wherein
the substrate processing apparatus includes
a discharge port,
a first supply path connected to the discharge port, and
a plurality of second supply paths respectively connected to the first supply path at a plurality of mixing positions having different flow-path lengths to the discharge port,
the substrate processing method includes
supplying the first processing liquid to the first supply path, and
supplying the second processing liquid to the first supply path through the plurality of second supply paths, and
at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.

16. A non-transitory computer readable recording medium storing a substrate processing program executed by a computer that controls a substrate processing apparatus, the substrate processing apparatus generating a third processing liquid using a first processing liquid and a second processing liquid and processing a substrate using the third processing liquid, wherein
the substrate processing apparatus includes
a discharge port for discharging the third processing liquid,
a first supply path connected to the discharge port, and
a plurality of second supply paths respectively connected to the first supply path at a plurality of mixing positions having different flow-path lengths to the discharge port,
the substrate processing program causes the computer to execute
a step of supplying the first processing liquid to the first supply path, and
a step of supplying the second processing liquid to the first supply path through the plurality of second supply paths, and
at the plurality of mixing positions of the first supply path, liquid in the first supply path is sequentially mixed with the second processing liquid, with mixing starting at the mixing position that is the farthest from the discharge port and finishing at the mixing position that is the closest from the discharge port.
